(19) United States
(12) Patent Application Publication
(10) Pub. No.: US 2026/0015714 A1
(43) Pub. Date: Jan. 15, 2026

(54) MASK FOR DEPOSITION AND ELECTRONIC DEVICE MANUFACTURED USING THE SAME

(71) Applicant: Samsung Display Co., Ltd., Yongin-si (KR)

(72) Inventors: JIHYUN JUNG, Yongin-si (KR); JEONGKUK KIM, Yongin-si (KR); SUNGWON CHO, Yongin-si (KR); JUNHO JO, Yongin-si (KR)

(21) Appl. No.: 19/170,878

(22) Filed: Apr. 4, 2025

(30) Foreign Application Priority Data
Jul. 11, 2024 (KR) 10-2024-0091606

(51) Int. Cl. C23C 16/04; C23C 14/04; H10K 59/12; H10K 71/16

(52) U.S. Cl. CPC C23C 16/042; C23C 14/042; H10K 71/166; H10K 59/12

(57) ABSTRACT

A deposition mask including: unit areas spaced apart from each other and a peripheral area surrounding the unit areas in a plan view; a base layer having a first surface and a second surface opposite to the first surface, the base layer defining first openings respectively corresponding to the unit areas; a pattern insulating layer including a material having a thermal expansion coefficient that is greater than a thermal expansion coefficient of the base layer, the pattern insulating layer having pattern portions respectively corresponding to the unit areas on the first surface of the base layer, each of the pattern portions defining a plurality of slits; and a reinforcement pattern in the peripheral area, the reinforcement pattern including a material having a thermal expansion coefficient that is different from the thermal expansion coefficient of the base layer, the reinforcement pattern being covered by the pattern insulating layer.

### CROSS-REFERENCE TO RELATED APPLICATION

This application claims priority to and the benefit of Korean Patent Application No. 10-2024-0091606, filed on Jul. 11, 2024, which is hereby incorporated by reference for all purposes as if fully set forth herein.

### BACKGROUND

### 1. Field

Aspects of embodiments of the present disclosure relate to a mask for deposition and an electronic device manufacturer using the same.

### 2. Description of the Related Art

Flat panel display devices are replacing cathode ray tube (CRT) display devices as the most common display devices due to their lightweight and thin characteristics. Liquid crystal display (LCD) devices and organic light emitting diode (OLED) display devices are some representative examples of such flat panel display devices.

A thin film, such as organic emission layers of the organic light emitting diode display devices, may be formed by using various methods. A deposition method refers to a method of depositing a deposition material on a substrate by using a mask having the same pattern as that of a thin film to be deposited on the substrate. If the mask is deformed due to stress induced in the mask during the deposition process, precise patterning on the substrate may be difficult.

### SUMMARY

Embodiments of the present disclosure provide a mask for deposition that achieves precise patterning.

Embodiments of the present disclosure also provide an electronic device manufactured using the mask for deposition.

Additional aspects and features of the present disclosure will be set forth in the description which follows and, in part, will be apparent from the description or may be learned by practice of the described embodiments.

A mask for deposition, according to an embodiment of the present disclosure, includes a plurality of unit areas spaced apart from each other and a peripheral area surrounding the unit areas in a plan view, a base layer having a first surface and a second surface opposite to the first surface and defining first openings respectively corresponding to the unit areas, a pattern insulating layer including a material having a thermal expansion coefficient that is greater than a thermal expansion coefficient of the base layer and including pattern portions respectively corresponding to the unit areas on the first surface of the base layer, and a reinforcement pattern in the peripheral area, including a material having a thermal expansion coefficient that is different from the thermal expansion coefficient of the base layer, and covered by the pattern insulating layer. Each of the pattern portions defines a plurality of slits.

In an embodiment, the thermal expansion coefficient of the reinforcement pattern may be greater than the thermal expansion coefficient of the base layer. The reinforcement pattern may be on the second surface of the base layer.

In an embodiment, the pattern insulating layer may include: a first portion on the first surface of the base layer and may include the pattern portions; and a second portion on the second surface of the base layer and defining second openings respectively corresponding to the unit areas. The reinforcement pattern may be covered by the second portion of the pattern insulating layer.

In an embodiment, the mask may further include an alignment pattern in the peripheral area on the first surface of the base layer and covered by the first portion of the pattern insulating layer.

In an embodiment, the reinforcement pattern may be spaced apart from the alignment pattern with the base layer interposed therebetween.

In an embodiment, a size of the reinforcement pattern may be greater than a size of the alignment pattern in the plan view.

In an embodiment, the first portion of the pattern insulating layer may define an alignment opening positioned in the peripheral area.

In an embodiment, the reinforcement pattern may overlap the alignment opening in the plan view.

In an embodiment, the peripheral area may have an alignment opening extending through the base layer, the pattern insulating layer, and the reinforcement pattern in a direction perpendicular to the first surface of the base layer.

In an embodiment, the thermal expansion coefficient of the reinforcement pattern may be less than the thermal expansion coefficient of the base layer. The reinforcement pattern may be on the first surface of the base layer.

In an embodiment, the pattern insulating layer may include: a first portion on the first surface of the base layer and including the pattern portions; and a second portion on the second surface of the base layer and defining second openings respectively corresponding to the unit areas. The reinforcement pattern may be covered by the first portion of the pattern insulating layer.

In an embodiment, the mask may further include an alignment pattern in the peripheral area on the first surface of the base layer and covered by the first portion of the pattern insulating layer. The alignment pattern and the reinforcement pattern may include a same material.

In an embodiment, the reinforcement pattern and the alignment pattern may be spaced apart from each other.

In an embodiment, the reinforcement pattern may surround the alignment pattern in the plan view.

In an embodiment, the mask may further include a cover insulating layer between the base layer and the pattern insulating layer in the peripheral area. The reinforcement pattern may be between the cover insulating layer and the pattern insulating layer.

In an embodiment, the base layer may include silicon, the cover insulating layer may include silicon oxide, the pattern insulating layer may include silicon nitride, and the reinforcement pattern may include a metal or an alloy.

In an embodiment, the reinforcement pattern may be adjacent to an edge of the base layer.

A mask for deposition, according to another embodiment of the present disclosure, includes a plurality of unit areas spaced apart from each other and a peripheral area surrounding the unit areas in a plan view, a base layer having a first surface and a second surface opposite to the first surface and defining first openings respectively corresponding to the unit areas, a pattern insulating layer including a material having a thermal expansion coefficient that is greater than a thermal expansion coefficient of the base layer and including a first portion on the first surface of the base layer including pattern portions respectively corresponding to the unit areas, and a second portion on the second surface of the base layer and defining second openings respectively corresponding to the unit areas, and a cover insulating layer including a material having a thermal expansion coefficient that is less than the thermal expansion coefficient of the base layer, is between the base layer and the first portion of the pattern insulating, and defines third openings respectively corresponding to the unit areas. Each of the pattern portions defines a plurality of slits. The first surface of the base layer contacts the cover insulating layer, and the second surface of the base layer contacts the second portion of the pattern insulating layer.

In an embodiment, a size of one of the second openings may be greater than a size of corresponding one of the first openings in the plan view.

A mask for deposition, according to another embodiment of the present disclosure, includes a plurality of unit areas spaced apart from each other and a peripheral area surrounding the unit areas in a plan view, a base layer having a first surface and a second surface opposite to the first surface and defining first openings respectively corresponding to the unit areas, a pattern insulating layer including a material having a thermal expansion coefficient that is less than a thermal expansion coefficient of the base layer and including a first portion on the first surface of the base layer and including pattern portions respectively corresponding to the unit areas and a second portion on the second surface of the base layer and defining second openings respectively corresponding to the unit areas, a reinforcement pattern in the peripheral area on the first portion of the pattern insulating layer and including a material having a thermal expansion coefficient that is greater than the thermal expansion coefficient of the base layer, and an alignment pattern in the peripheral area on the first portion of the pattern insulating layer. Each of the pattern portions defines a plurality of slits. The alignment pattern and the reinforcement pattern include a same material

In an embodiment, the reinforcement pattern and the alignment pattern may be spaced apart from each other.

In an embodiment, in a plan view, the reinforcement pattern may surround the alignment pattern in the plan view.

An electronic device, according to another embodiment of the present disclosure, includes a display device including an emission layer deposited by using a mask for deposition and a processor configured to provide an image data signal and an input control signal to the display device to control the display device. The mask includes a plurality of unit areas spaced apart from each other and a peripheral area surrounding the unit areas in a plan view, a base layer having a first surface and a second surface opposite to the first surface and defining first openings respectively corresponding to the unit areas, a pattern insulating layer including a material having a thermal expansion coefficient that is greater than a thermal expansion coefficient of the base layer and including pattern portions respectively corresponding to the unit areas on the first surface of the base layer, and a reinforcement pattern in the peripheral area, including a material having a thermal expansion coefficient that is different from the thermal expansion coefficient of the base layer, and covered by the pattern insulating layer. Each of the pattern portions defines a plurality of slits.

According to embodiments of the present disclosure, the mask for deposition achieves precise patterning.

It is to be understood that both the foregoing general description and the following detailed description are exemplary and explanatory and are intended to provide further explanation of the present disclosure as claimed.

### BRIEF DESCRIPTION OF THE DRAWINGS

The accompanying drawings, which are included to provide a further understanding of the present disclosure and are incorporated in and constitute a part of this specification, illustrate embodiments of the present disclosure, and together with the description, describe aspects and features of the present disclosure. In the drawings:

FIG. 1 is a cross-sectional view illustrating a deposition apparatus according to an embodiment.

FIG. 2 is a top view illustrating a mask according to an embodiment.

FIG. 3 is a cross-sectional view taken along the line I-I′ in FIG. 2.

FIG. 4 is a cross-sectional view taken along the line II-II′ in FIG. 2.

FIGS. 5A to 5D are bottom views illustrating some components of a mask according to an embodiment.

FIGS. 6A to 6E are cross-sectional views illustrating steps of a method for manufacturing a mask according to an embodiment.

FIGS. 7 and 8 are cross-sectional views illustrating a mask according to an embodiment.

FIGS. 9A and 9B are cross-sectional views illustrating steps of a method for manufacturing a mask according to an embodiment.

FIGS. 10 and 11 are cross-sectional views illustrating a mask according to an embodiment.

FIGS. 12A to 12E are cross-sectional views illustrating steps of a method for manufacturing a mask according to an embodiment.

FIGS. 13 and 14 are cross-sectional views illustrating a mask according to an embodiment.

FIGS. 15A and 15B are top views illustrating some components of a mask according to an embodiment.

FIGS. 16A and 16B are cross-sectional views illustrating steps of a method for manufacturing a mask according to an embodiment.

FIGS. 17 and 18 are cross-sectional views illustrating a mask according to an embodiment.

FIGS. 19A to 19E are cross-sectional views illustrating steps of a method for manufacturing a mask according to an embodiment.

FIGS. 20 and 21 are cross-sectional views illustrating a mask according to an embodiment.

FIG. 22 is a cross-sectional view illustrating a display device according to an embodiment.

FIG. 23 is a block diagram describing an electronic device according to an embodiment.

FIG. 24 is a schematic diagram showing electronic devices according to various embodiments.

### DETAILED DESCRIPTION

Various example embodiments will be described more fully hereinafter with reference to the accompanying drawings, in which some embodiments of the present disclosure are shown. The present disclosure may, however, be embodied in many different forms and should not be construed as limited to the embodiments set forth herein. Rather, these embodiments are provided so that this disclosure will be thorough and complete and will fully convey the scope of the present disclosure to those skilled in the art.

In the disclosure, various modifications can be made, various forms can be used, and specific embodiments will be illustrated in the drawings and described, in detail, in the text. However, this is not intended to limit the disclosure to a specific form disclosed, and it will be understood that all changes, equivalents, or substitutes which fall in the spirit and technical scope of the present disclosure should be included.

It will be understood that when an element or layer is referred to as being “on,” “connected to,” or “coupled to” another element or layer, it may be directly on, connected, or coupled to the other element or layer or one or more intervening elements or layers may also be present. When an element or layer is referred to as being “directly on,” “directly connected to,” or “directly coupled to” another element or layer, there are no intervening elements or layers present. For example, when a first element is described as being “coupled” or “connected” to a second element, the first element may be directly coupled or connected to the second element or the first element may be indirectly coupled or connected to the second element via one or more intervening elements.

In the figures, dimensions of the various elements, layers, etc. may be exaggerated for clarity of illustration. The same reference numerals designate the same elements. As used herein, the term “and/or” includes any and all combinations of one or more of the associated listed items. Further, the use of “may” when describing embodiments of the present disclosure relates to “one or more embodiments of the present disclosure.” Expressions, such as “at least one of” and “any one of,” when preceding a list of elements, modify the entire list of elements and do not modify the individual elements of the list. For example, the expression “at least one of a, b, or c” indicates only a, only b, only c, both a and b, both a and c, both b and c, all of a, b, and c, or variations thereof. As used herein, the terms “use,” “using,” and “used” may be considered synonymous with the terms “utilize,” “utilizing,” and “utilized,” respectively. As used herein, the terms “substantially,” “about,” and similar terms are used as terms of approximation and not as terms of degree, and are intended to account for the inherent variations in measured or calculated values that would be recognized by those of ordinary skill in the art.

It will be understood that, although the terms first, second, third, etc. may be used herein to describe various elements, components, regions, layers, and/or sections, these elements, components, regions, layers, and/or sections should not be limited by these terms. These terms are used to distinguish one element, component, region, layer, or section from another element, component, region, layer, or section. Thus, a first element, component, region, layer, or section discussed below could be termed a second element, component, region, layer, or section without departing from the teachings of example embodiments.

Spatially relative terms, such as “beneath,” “below,” “lower,” “above,” “upper,” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” or “over” the other elements or features. Thus, the term “below” may encompass both an orientation of above and below. The device may be otherwise oriented (rotated 90 degrees or at other orientations), and the spatially relative descriptors used herein should be interpreted accordingly.

The terminology used herein is for the purpose of describing embodiments of the present disclosure and is not intended to be limiting of the present disclosure. As used herein, the singular forms “a” and “an” are intended to include the plural forms as well, unless the context clearly indicates otherwise. It will be further understood that the terms “includes,” “including,” “comprises,” and/or “comprising,” when used in this specification, specify the presence of stated features, integers, steps, operations, elements, and/or components but do not preclude the presence or addition of one or more other features, integers, steps, operations, elements, components, and/or groups thereof.

A person of ordinary skill in the art would appreciate, in view of the present disclosure in its entirety, that each suitable feature of the various embodiments of the present disclosure may be combined or combined with each other, partially or entirely, and may be technically interlocked and operated in various suitable ways, and each embodiment may be implemented independently of each other or in conjunction with each other in any suitable manner unless otherwise stated or implied.

Also, any numerical range disclosed and/or recited herein is intended to include all sub-ranges of the same numerical precision subsumed within the recited range. For example, a range of “1.0 to 10.0” is intended to include all subranges between (and including) the recited minimum value of 1.0 and the recited maximum value of 10.0, that is, having a minimum value equal to or greater than 1.0 and a maximum value equal to or less than 10.0, such as, for example, 2.4 to 7.6. Any maximum numerical limitation recited herein is intended to include all lower numerical limitations subsumed therein, and any minimum numerical limitation recited in this specification is intended to include all higher numerical limitations subsumed therein. Accordingly, Applicant reserves the right to amend this specification, including the claims, to expressly recite any sub-range subsumed within the ranges expressly recited herein. All such ranges are intended to be inherently described in this specification such that amending to expressly recite any such subranges would comply with the requirements of 35 U.S.C. § 112(a) and 35 U.S.C. § 132(a).

The electronic device and/or any other relevant devices or components according to embodiments of the present disclosure described herein may be implemented utilizing any suitable hardware, firmware (e.g., an application-specific integrated circuit), software, and/or a suitable combination of software, firmware, and hardware. For example, the various components of the electronic device may be formed on one integrated circuit (IC) chip or on separate IC chips. Further, the various components of the electronic device may be implemented on a flexible printed circuit film, a tape carrier package (TCP), a printed circuit board (PCB), or formed on a same substrate as the electronic device. Further, the various components of the electronic device may be a process or thread, running on one or more processors, in one or more computing devices, executing computer program instructions and interacting with other system components for performing the various functionalities described herein. The computer program instructions are stored in a memory which may be implemented in a computing device using a standard memory device, such as, for example, a random access memory (RAM). The computer program instructions may also be stored in other non-transitory computer readable media such as, for example, a CD-ROM, flash drive, or the like. Also, a person of skill in the art should recognize that the functionality of various computing devices may be combined or integrated into a single computing device or the functionality of a particular computing device may be distributed across one or more other computing devices without departing from the scope of the exemplary embodiments of the present disclosure.

Unless otherwise defined, all terms (including technical and scientific terms) used herein have the same meaning as commonly understood by one of ordinary skill in the art to which this inventive concept belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

Hereinafter, embodiments will be described in detail with reference to the accompanying drawings. The same reference numerals are used for the same components in the drawings, and redundant descriptions of the same components will be omitted.

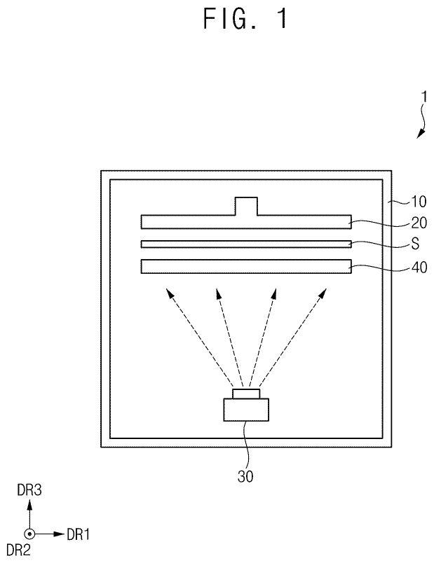

FIG. 1 is a cross-sectional view illustrating a deposition apparatus according to an embodiment.

Referring to FIG. 1, a deposition apparatus 1, according to an embodiment, may include a deposition chamber 10, a fixing member 20, a deposition source 30, and a mask 40.

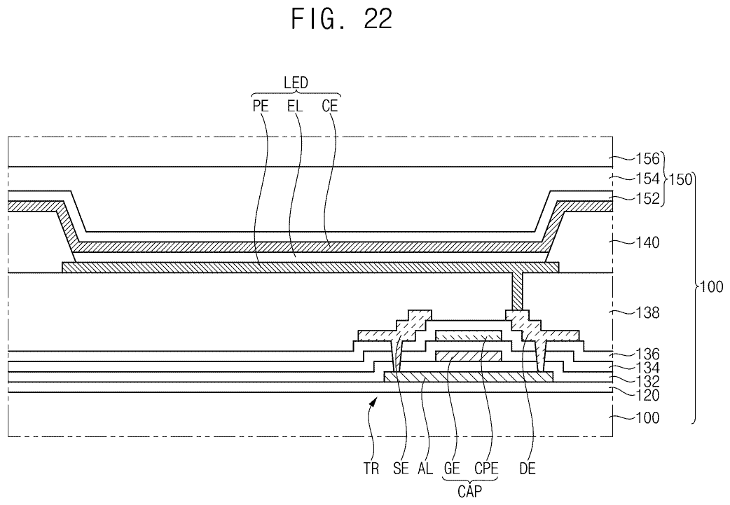

The deposition chamber 10 may provide a space in which a deposition process for forming a thin film, such as an organic emission layer (e.g., an emission layer EL shown in FIG. 22), on a substrate S is performed. The deposition chamber 10 may set a deposition condition to a vacuum state. The deposition chamber 10 may have a bottom surface, a ceiling surface, and side walls. The bottom surface of the deposition chamber 10 may be parallel to a plane defined by a first direction DR1 and a second direction DR2 crossing (e.g., intersecting) the first direction DR1. For example, the second direction DR2 may be perpendicular to the first direction DR1. A third direction DR3 may be defined as a direction normal to (e.g., perpendicular to) the bottom surface of the deposition chamber 10.

The fixing member 20 may be disposed inside the deposition chamber 10 and may be disposed above the deposition source 30. The fixing member 20 may be configured to fix (e.g., to secure) the mask 40. In an embodiment, the fixing member 20 may be installed on (or fixed onto) the ceiling surface of the deposition chamber 10. The fixing member 20 may include a magnet, a jig, a robot arm, or the like for fixing the mask 40. For example, the fixing member 20 may fix the mask 40 with magnetic force, thereby causing the mask 40 to be in close contact with the substrate S.

The deposition source 30 may spray (or emit) a deposition material, such as an organic light emitting material, as a vapor. The deposition material sprayed from the deposition source 30 may pass through the mask 40 and may be deposited on one surface of the substrate S to form patterns. For example, the substrate S may be a substrate in an intermediate stage of manufacturing a display panel, but embodiments are not limited thereto.

The mask 40 may be disposed inside the deposition chamber 10 and may be disposed above the deposition source 30. The mask 40 may support the substrate S. As described below, the mask 40 may include a plurality of unit areas, and a plurality of slits may be defined in each of the unit areas. The deposition material sprayed from the deposition source 30 may pass through the slits of the mask 40 and may be deposited on one surface of the substrate S to form certain patterns. For example, the substrate S may be a mother substrate for manufacturing a plurality of display panels. In such an embodiment, the substrate S may include a plurality of cell areas, and the unit areas of the mask 40 may respectively correspond to the cell areas of the substrate S.

In an embodiment, a support block or the like for supporting the mask 40 may be further disposed inside the deposition chamber 10.

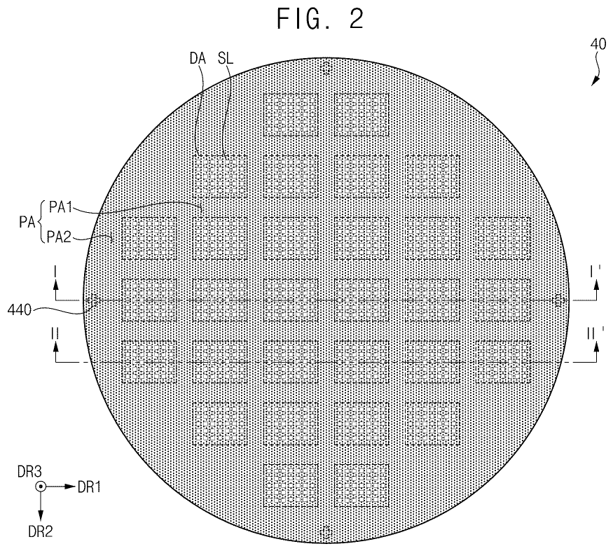

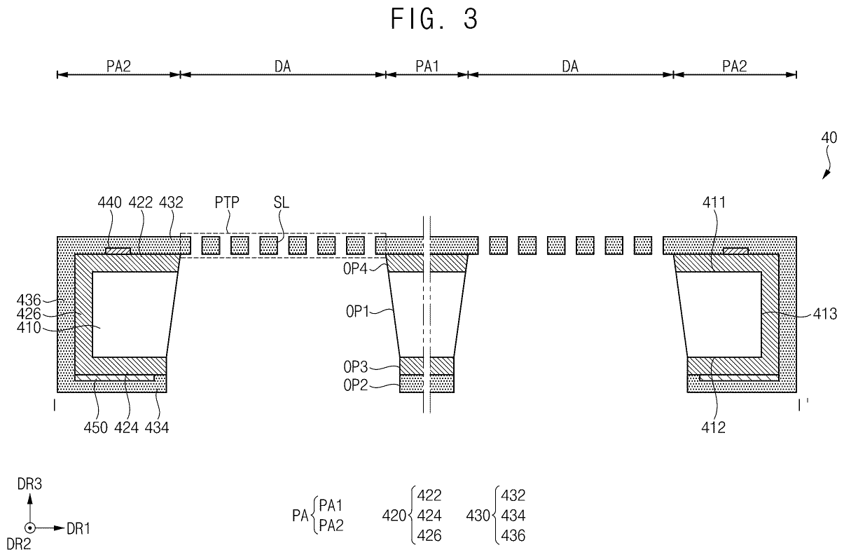

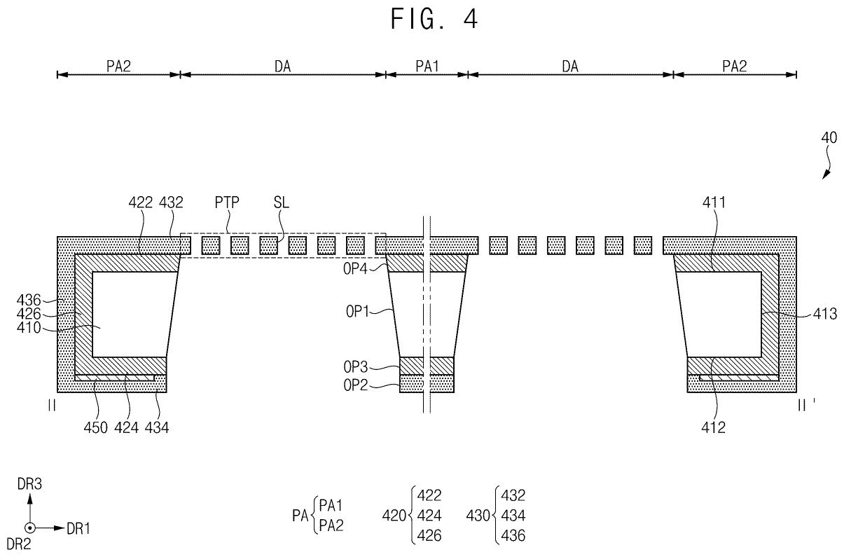

FIG. 2 is a top view illustrating a mask according to an embodiment. FIG. 3 is a cross-sectional view taken along the line I-I′ in FIG. 2. FIG. 4 is a cross-sectional view taken along the line II-II′ in FIG. 2.

Referring to FIGS. 1 to 4, in an embodiment, the mask 40 may include a base layer 410, a cover insulating layer 420, a pattern insulating layer 430, an alignment pattern 440, and a reinforcement pattern 450.

The mask 40 (or the base layer 410) may have a plurality of unit areas DA and a peripheral area PA surrounding the unit areas DA. As illustrated in FIG. 2, the unit areas DA may be spaced apart from each other in a plan view. Although FIG. 2 illustrates an embodiment in which the mask 40 has a circular planar shape, this is an example and embodiments are not limited thereto. The mask 40 may have various planar shapes, such as a square or the like.

The peripheral area PA may include a first peripheral area PA1 and a second peripheral area PA2. The first peripheral area PA1 may be defined as an area between adjacent unit areas DA. For example, the first peripheral area PA1 may have a grid shape (or lattice shape) in a plan view. The second peripheral area PA2 may be defined as an outer area of the unit areas DA and the first peripheral area PA1. For example, the second peripheral area PA2 may have a ring shape in a plan view.

In an embodiment, the base layer 410 may include the same material as the substrate S, which is the deposition target. For example, the base layer 410 may include silicon. For example, the base layer 410 may be formed by slimming (or thinning) a silicon wafer. Because the base layer 410 and the substrate S include the same material (such that a thermal expansion coefficient of the base layer 410 is equal to a thermal expansion coefficient of the substrate S), a deposition position of the deposition material may be prevented from being distorted depending on a process temperature.

The base layer 410 may have a first surface 411 and a second surface 412 opposite to the first surface 411. The first surface 411 of the base layer 410 may be a surface facing the substrate S, which is the deposition target. The second surface 412 of the base layer 410 may be a surface facing a deposition source 30, which sprays the deposition material. The third direction DR3 may be perpendicular to each of the first surface 411 and the second surface 412 of the base layer 410. Hereinafter, the first surface 411 may be referred to as an upper surface, and the second surface 412 may be referred to as a lower surface. An outer side surface 413 of the base layer 410 may connect (e.g., may extend between) the first surface 411 and the second surface 412.

The cover insulating layer 420 may be disposed between the base layer 410 and the pattern insulating layer 430. The cover insulating layer 420 may cover at least a portion of the base layer 410. For example, as illustrated in FIGS. 3 and 4, the cover insulating layer 420 may cover the first surface 411, the second surface 412, and the outer side surface 413 of the base layer 410.

In an embodiment, the cover insulating layer 420 may include a first portion 422 disposed on the first surface 411 of the base layer 410, a second portion 424 disposed on the second surface 412 of the base layer 410, and a third portion 426 disposed on the outer side surface 413 of the base layer 410. The first portion 422 and the second portion 424 of the cover insulating layer 420 may be positioned in opposite directions to each other with the base layer 410 interposed therebetween. For example, the first to third portions 422, 424, and 426 of the cover insulating layer 420 may be connected to each other.

The first portion 422 of the cover insulating layer 420 may contact the first surface 411 of the base layer 410. The second portion 424 of the cover insulating layer 420 may contact the second surface 412 of the base layer 410. The third portion 426 of the cover insulating layer 420 may contact the outer side surface 413 of the base layer 410.

The cover insulating layer 420 may include a different material from the base layer 410. In an embodiment, the cover insulating layer 420 may include a material having a thermal expansion coefficient that is less than a thermal expansion coefficient of the base layer 410. For example, the cover insulating layer 420 may include silicon oxide, but this is an example and embodiments are not limited thereto.

The pattern insulating layer 430 may cover at least a portion of the cover insulating layer 420. For example, as illustrated in FIGS. 3 and 4, the pattern insulating layer 430 may cover the first to third portions 422, 424, and 426 of the cover insulating layer 420. In another embodiment, the pattern insulating layer 430 may cover the first and second portions 422 and 424 of the cover insulating layer 420 but may not cover the third portion 426 of the cover insulating layer 420.

In an embodiment, the pattern insulating layer 430 may include a first portion 432 disposed on the first surface 411 of the base layer 410, a second portion 434 disposed on the second surface 412 of the base layer 410, and a third portion 436 disposed on the outer side surface 413 of the base layer 410. The first portion 432 of the pattern insulating layer 430 may be disposed on an upper surface of the first portion 422 of the cover insulating layer 420, and the second portion 434 of the pattern insulating layer 430 may be disposed on a lower surface of the second portion 424 of the cover insulating layer 420. The first portion 432 and the second portion 434 of the pattern insulating layer 430 may be positioned in opposite directions to each other with the base layer 410 and the cover insulating layer 420 interposed therebetween. For example, the first to third portions 432, 434, and 436 of the pattern insulating layer 430 may be connected to each other.

The first portion 432 of the pattern insulating layer 430 may contact the first portion 422 of the cover insulating layer 420. The second portion 434 of the pattern insulating layer 430 may contact the second portion 424 of the cover insulating layer 420. The third portion 436 of the pattern insulating layer 430 may contact the third portion 426 of the cover insulating layer 420.

The pattern insulating layer 430 may include pattern portions PTP respectively corresponding to the unit areas DA on the first surface 411 of the base layer 410. The first portion 432 of the pattern insulating layer 430 may include the pattern portions PTP. Each of the pattern portions PTP may define a plurality of slits SL. Each of the slits SL may penetrate (e.g., may extend through) the first portion 432 of the pattern insulating layer 430 in the third direction DR3. For example, each of the pattern portions PTP may have a grid shape in a plan view. For example, one pattern portion PTP defining a plurality of slits SL may correspond to one unit area DA. As illustrated in FIGS. 3 and 4, another layer may not be (e.g., no layers may be) disposed below the pattern portion PTP. The base layer 410 may define first openings OP1 respectively corresponding to the unit areas DA. For example, one first opening OP1 may correspond to one unit area DA. Each of the first openings OP1 may penetrate the base layer 410 in the third direction DR3. The first openings OP1 may be spaced apart from each other in a plan view.

The second portion 434 of the pattern insulating layer 430 may define second openings OP2 respectively corresponding to the unit areas DA. For example, one second opening OP2 may correspond to one unit area DA. Each of the second openings OP2 may penetrate the second portion 434 of the pattern insulating layer 430 in the third direction DR3. The second openings OP2 may be spaced apart from each other in a plan view.

While the first portion 432 of the pattern insulating layer 430 includes the pattern portions PTP respectively corresponding to the unit areas DA, the second portion 434 of the pattern insulating layer 430 defines the second openings OP2 respectively corresponding to the unit areas DA, so that, in a plan view, a size of the second portion 434 of the pattern insulating layer 430 may be less than a size of the first portion 432 of the pattern insulating layer 430.

The second portion 424 of the cover insulating layer 420 may define third openings OP3 respectively corresponding to the unit areas DA. For example, one third opening OP3 may correspond to one unit area DA. Each of the third openings OP3 may penetrate the second portion 424 of the cover insulating layer 420 in the third direction DR3. The third openings OP3 may be spaced apart from each other in a plan view.

The first portion 422 of the cover insulating layer 420 may define fourth openings OP4 respectively corresponding to the unit areas DA. For example, one fourth opening OP4 may correspond to one unit area DA. Each of the fourth openings OP4 may penetrate the first portion 422 of the cover insulating layer 420 in the third direction DR3. The fourth openings OP4 may be spaced apart from each other in a plan view. In a plan view, a size of the first portion 422 of the cover insulating layer 420 may be similar to a size of the second portion 424 of the cover insulating layer 420.

As illustrated in FIGS. 3 and 4, the first to fourth openings OP1, OP2, OP3, and OP4 corresponding to one unit area DA may be connected to (e.g., aligned with) each other in the third direction DR3. For example, another layer may not be disposed below each of the pattern portions PTP. Therefore, the deposition material sprayed from the deposition source 30 may pass through the slits SL defined in each of the pattern portions PTP and may be deposited on one surface of the substrate S to form patterns.

In an embodiment, in a plan view, each of the base layer 410, the first portion 422 of the cover insulating layer 420, the second portion 424 of the cover insulating layer 420, and the second portion 434 of the pattern insulating layer 430 may overlap the first peripheral area PA1 and the second peripheral area PA2 and may have a grid shape.

The pattern insulating layer 430 may include a different material from the base layer 410 and the cover insulating layer 420. In an embodiment, the pattern insulating layer 430 may include a material having a thermal expansion coefficient that is greater than the thermal expansion coefficient of the base layer 410. In addition, the pattern insulating layer 430 may include a transparent material or a translucent material. For example, the pattern insulating layer 430 may include silicon nitride, but this is an example and embodiments are not limited thereto.

The alignment pattern 440 may be disposed in the peripheral area PA on the first surface 411 of the base layer 410. The alignment pattern 440 may be disposed in the second peripheral area PA2. The alignment pattern 440 may be used to align the mask 40 and the substrate S with each other.

In an embodiment, the alignment pattern 440 may include a plurality of alignment patterns 440. For example, as illustrated in FIG. 2, in a plan view, the alignment patterns 440 may be disposed on the left, right, upper, and lower sides of the mask 40, respectively, but this is an example and embodiments are not limited thereto. In addition, although FIG. 2 illustrates an embodiment in which each of the alignment patterns 440 has a cross planar shape, this is an example and embodiments are not limited thereto. The number and the shape of the alignment patterns 440 may be variously changed.

The alignment pattern 440 may be disposed between the cover insulating layer 420 and the pattern insulating layer 430. The alignment pattern 440 may be disposed between the first portion 422 of the cover insulating layer 420 and the first portion 432 of the pattern insulating layer 430. For example, the alignment pattern 440 may be disposed on the upper surface of the first portion 422 of the cover insulating layer 420 and may be covered by the first portion 432 of the pattern insulating layer 430. A thickness of the first portion 432 of the pattern insulating layer 430 may be greater than a thickness of the alignment pattern 440.

In an embodiment, the alignment pattern 440 may include a metal or alloy, such as chromium, aluminum, tungsten, silver, or the like. As described above, the pattern insulating layer 430 may include a transparent material or a translucent material. Therefore, even when the alignment pattern 440 is covered by the first portion 432 of the pattern insulating layer 430, the alignment pattern 440 may be visible from the outside.

The reinforcement pattern 450 may be disposed in the peripheral area PA on the second surface 412 of the base layer 410. The reinforcement pattern 450 may be disposed in a portion of the peripheral area PA. The alignment pattern 440 and the reinforcement pattern 450 may be positioned in opposite directions to each other with the base layer 410 and the cover insulating layer 420 interposed therebetween.

The reinforcement pattern 450 may be disposed between the cover insulation layer 420 and the pattern insulation layer 430. The reinforcement pattern 450 may be disposed between the second portion 424 of the cover insulation layer 420 and the second portion 434 of the pattern insulation layer 430. For example, the reinforcement pattern 450 may be disposed on the lower surface of the second portion 424 of the cover insulation layer 420 and may be covered by the second portion 434 of the pattern insulation layer 430. A thickness of the second portion 434 of the pattern insulation layer 430 may be greater than a thickness of the reinforcement pattern 450.

The reinforcement pattern 450 may include a material having a thermal expansion coefficient that is different from the thermal expansion coefficient of the base layer 410. In an embodiment, the reinforcement pattern 450 may include a material having a thermal expansion coefficient that is greater than the thermal expansion coefficient of the base layer 410. For example, the reinforcement pattern 450 may include a metal or alloy, such as chromium, aluminum, tungsten, silver, or the like. In another embodiment, the reinforcement pattern 450 may include an insulating material.

As described above, because the thermal expansion coefficient of the pattern insulating layer 430 is greater than the thermal expansion coefficient of the base layer 410, tensile stress may be induced in the pattern insulating layer 430. Because the tensile stress is induced in each of the first portion 432 and the second portion 434 of the pattern insulating layer 430, which are positioned in opposite directions to each other with the base layer 410 interposed therebetween, the tensile stress induced in the first portion 432 of the pattern insulating layer 430 may be offset to some extent by the tensile stress induced in the second portion 434 of the pattern insulating layer 430. However, as described above, because the size of the second portion 434 of the pattern insulating layer 430 is less than the size of the first portion 432 of the pattern insulating layer 430 in a plan view, the tensile stress induced in the first portion 432 of the pattern insulating layer 430 may not be completely offset. Further, because the thermal expansion coefficient of the cover insulating layer 420 is less than the thermal expansion coefficient of the base layer 410, a compressive stress may be induced in the cover insulating layer 420. However, because the size of the first portion 422 of the cover insulating layer 420 may be similar to the size of the second portion 424 of the cover insulating layer 420 in a plan view, the tensile stress induced in the first portion 432 of the pattern insulating layer 430 may not be substantially offset by the cover insulating layer 420. In such an embodiment, a warpage, in which the mask 40 is deformed by the tensile stress that is induced in the first portion 432 of the pattern insulating layer 430 and is not offset, may occur, and the deposition position of the deposition material may be different from the target position depending on the mask position, making precise patterning difficult.

According to embodiments of the present disclosure, the reinforcement pattern 450 may be disposed in the peripheral area PA to further offset the tensile stress induced in the first portion 432 of the pattern insulating layer 430. For example, when the reinforcement pattern 450 includes a material having a thermal expansion coefficient that is greater than the thermal expansion coefficient of the base layer 410 (e.g., when the tensile stress is induced in the reinforcement pattern 450), the reinforcement pattern 450 may be positioned in a direction opposite to the first portion 432 of the pattern insulating layer 430 with the base layer 410 interposed therebetween. Because the reinforcement pattern 450 in which the tensile stress is induced is positioned in a direction opposite to the first portion 432 of the pattern insulating layer 430 with the base layer 410 interposed therebetween, the tensile stress induced in the first portion 432 of the pattern insulating layer 430 may be offset more effectively. Therefore, warpage of the mask 40 may be reduced, and precise patterning may be possible.

The reinforcement pattern 450 may have various planar shapes to effectively offset the tensile stress induced in the first portion 432 of the pattern insulating layer 430. In an embodiment, the reinforcement pattern 450 may be primarily disposed in an outer area of the mask 40.

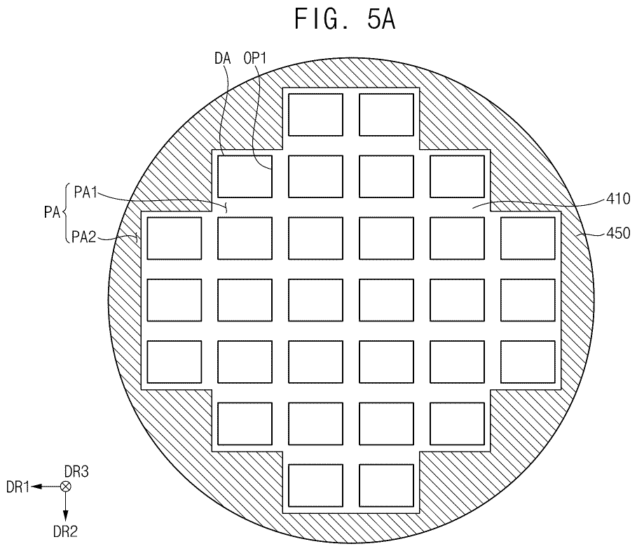

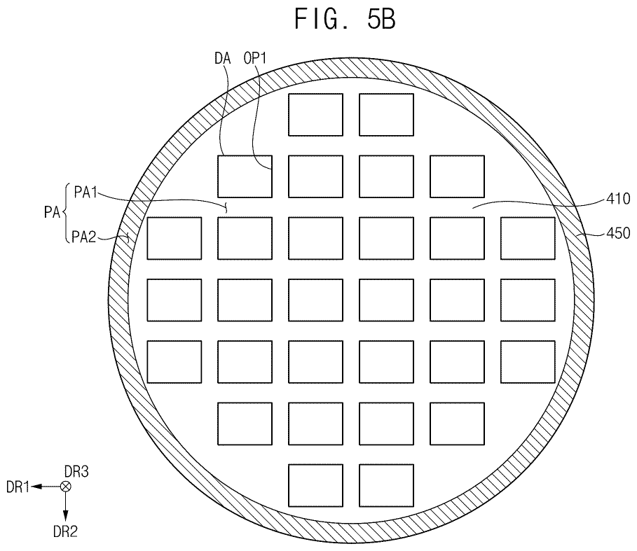

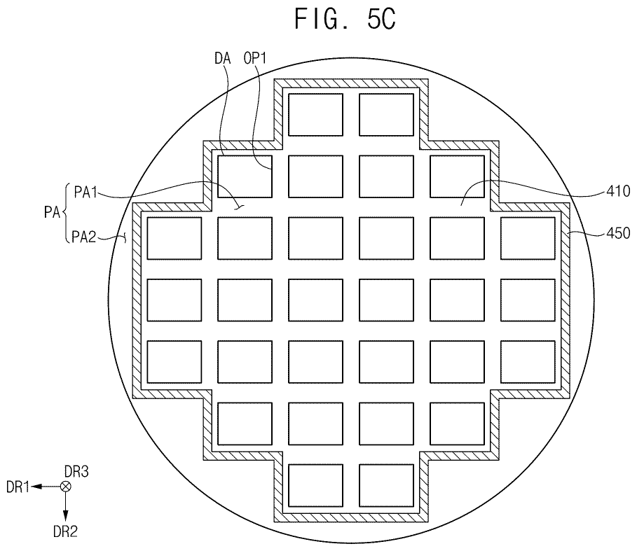

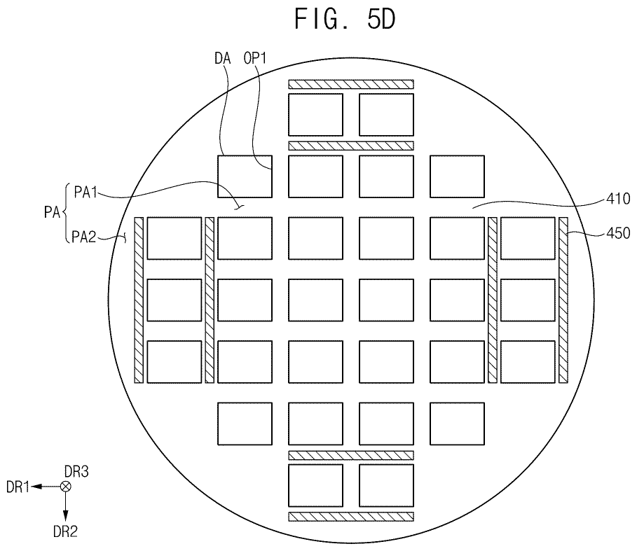

FIGS. 5A to 5D are bottom views illustrating some components of a mask according to an embodiment. For example, each of FIGS. 5A to 5D may illustrate the base layer 410 and the reinforcement pattern 450.

In an embodiment, as illustrated in FIGS. 5A to 50, the reinforcement pattern 450 may be disposed adjacent to an outer edge of the base layer 410. The reinforcement pattern 450 may be disposed in the second peripheral area PA2 and may have a shape that surrounds the unit areas DA in a plan view. For example, the reinforcement pattern 450 may have a ring shape in a plan view.

In an embodiment, as illustrated in FIG. 5D, a plurality of reinforcement patterns 450 may be disposed spaced apart from each other. For example, some of the reinforcement patterns 450 may be disposed in the first peripheral area PA1, and some of the reinforcement patterns 450 may be disposed in the second peripheral area PA2.

The shape of the reinforcement pattern 450 illustrated in FIGS. 5A to 5D are examples, and embodiments are not limited thereto. The shape and arrangement of the reinforcement pattern 450 may be variously changed.

Referring again to FIGS. 2 to 4, in an embodiment, the alignment pattern 440 and the reinforcement pattern 450 may be positioned in opposite directions to each other with the base layer 410 and the cover insulating layer 420 interposed therebetween. For example, the reinforcement pattern 450 may be spaced apart from the alignment pattern 440 with the base layer 410 and the cover insulating layer 420 interposed therebetween.

In an embodiment, a thermal expansion coefficient of the alignment pattern 440 may be greater than the thermal expansion coefficient of the base layer 410. In a plan view, a size of the reinforcement pattern 450 may be greater than a size of the alignment pattern 440. If the size of the reinforcement pattern 450 is less than the size of the alignment pattern 440, the tensile stress induced in the first portion 432 of the pattern insulating layer 430 may not be effectively offset.

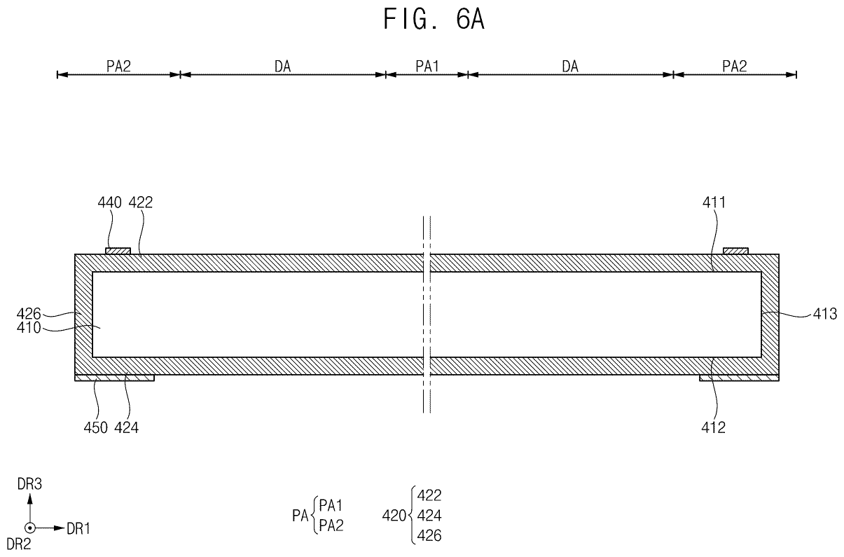

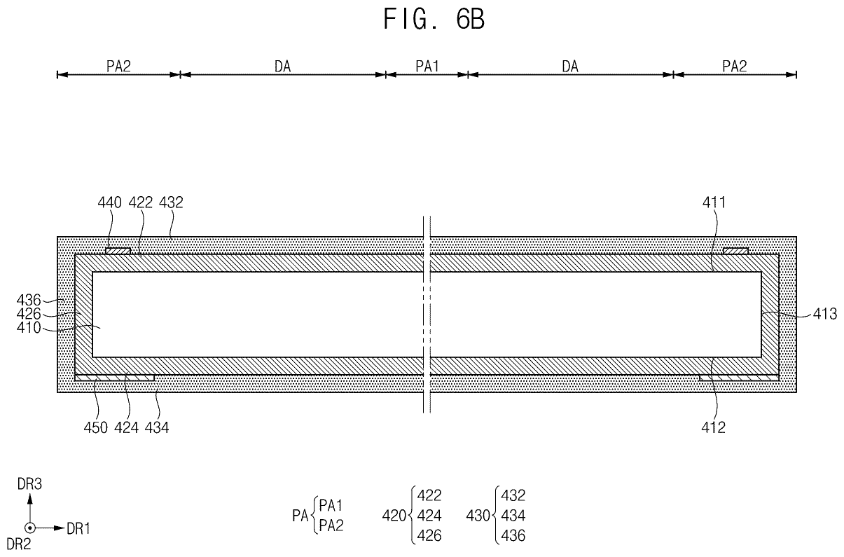

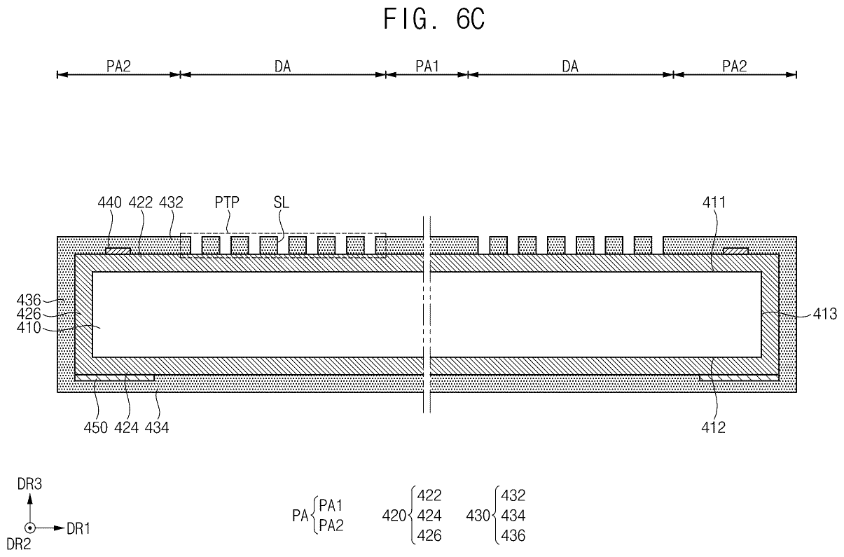

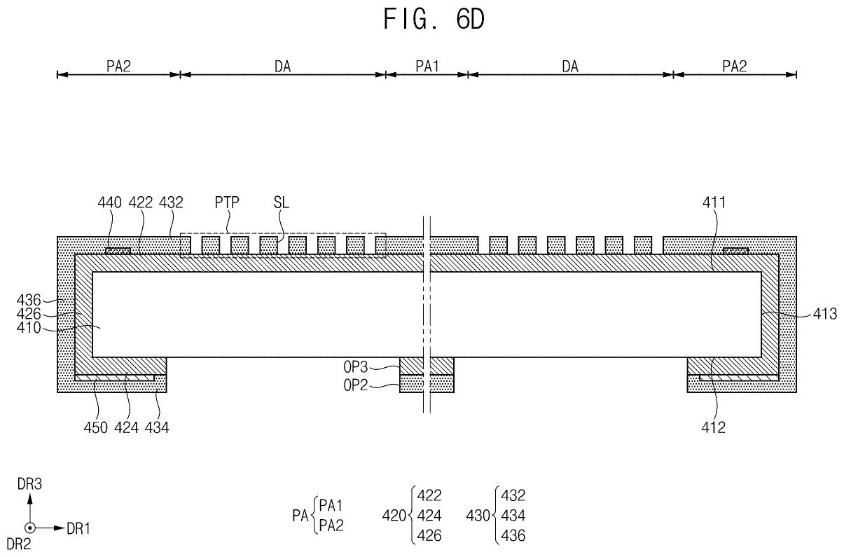

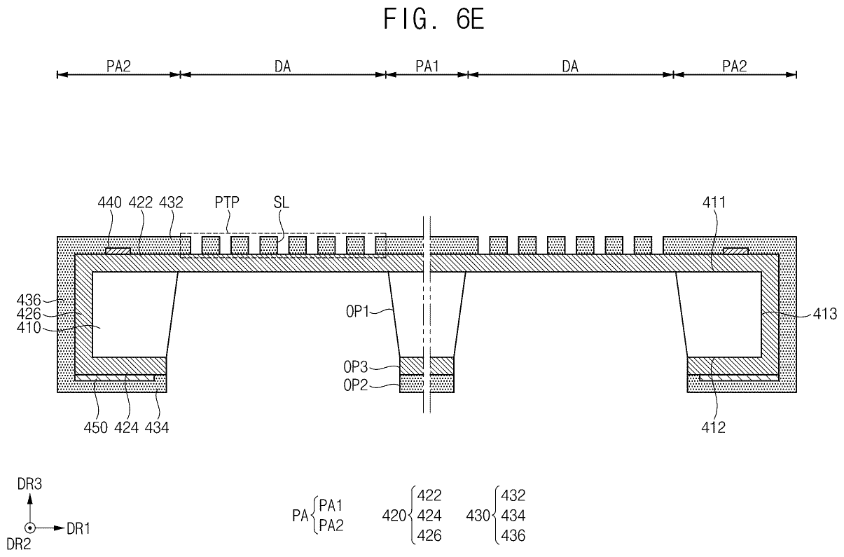

FIGS. 6A to 6E are cross-sectional views illustrating steps of a method for manufacturing a mask according to an embodiment.

Each of FIGS. 6A to 6E may correspond to the cross-sectional view shown in FIG. 3. FIGS. 6A to 6E may illustrate steps of a method for manufacturing the mask 40 described above with reference to FIGS. 2 to 4, and repeated descriptions may be omitted or simplified.

Referring to FIG. 6A, the cover insulating layer 420 may be formed on the base layer 410. The cover insulating layer 420 may be formed to cover at least a portion of the base layer 410. For example, the cover insulating layer 420 may be formed to cover the first surface 411, the second surface 412, and the outer side surface 413 of the base layer 410. The cover insulating layer 420 may include the first portion 422 disposed on the first surface 411 of the base layer 410, the second portion 424 disposed on the second surface 412 of the base layer 410, and the third portion 426 disposed on the outer side surface 413 of the base layer 410.

In an embodiment, the cover insulating layer 420 may be formed by oxidizing the base layer 410. For example, the base layer 410 may include silicon, and the cover insulating layer 420 may include silicon oxide. However, this is an example, and embodiments are not limited thereto.

The alignment pattern 440 and the reinforcement pattern 450 may be formed on the cover insulating layer 420.

The alignment pattern 440 may be formed on the upper surface of the first portion 422 of the cover insulating layer 420. For example, after depositing a first thin film on the upper surface of the first portion 422 of the cover insulating layer 420, the first thin film may be partially removed by a photolithography process and an etching process to form the alignment pattern 440.

The reinforcement pattern 450 may be formed on the lower surface of the second portion 424 of the cover insulating layer 420. For example, after depositing a second thin film on the lower surface of the second portion 424 of the cover insulating layer 420, the second thin film may be partially removed by a photolithography process and an etching process to form the reinforcement pattern 450. The second thin film may be formed by depositing a material, such as a metal or an alloy, having a thermal expansion coefficient that is greater than the thermal expansion coefficient of the base layer 410.

In an embodiment, the reinforcement pattern 450 may be formed primarily on an outer area of the base layer 410. In an embodiment, when the base layer 410 is formed of a silicon wafer, a crystal direction of the silicon wafer may be measured, and a shape of the reinforcement pattern 450 may be determined based on the measured crystal direction of the silicon wafer.

In an embodiment, the alignment pattern 440 and the reinforcement pattern 450 may be formed not simultaneously (e.g., may be formed sequentially). For example, the reinforcement pattern 450 may be formed after the alignment pattern 440 is formed. In another embodiment, the alignment pattern 440 may be formed after the reinforcement pattern 450 is formed.

Referring to FIG. 6B, the pattern insulating layer 430 may be formed on the cover insulating layer 420, the alignment pattern 440, and the reinforcement pattern 450. The pattern insulating layer 430 may include the first portion 432 disposed on the upper surface of the first portion 422 of the cover insulating layer 420 and the second portion 434 disposed on the lower surface of the second portion 424 of the cover insulating layer 420. The first portion 432 of the pattern insulating layer 430 may cover the alignment pattern 440. The second portion 434 of the pattern insulating layer 430 may cover the reinforcement pattern 450.

The pattern insulating layer 430 may be formed by depositing a transparent material or a translucent material having a thermal expansion coefficient that is greater than the thermal expansion coefficient of the base layer 410. For example, the pattern insulating layer 430 may be formed by depositing silicon nitride by a process, such as chemical vapor deposition (“CVD”), physical vapor deposition (“PVD”), or the like, but embodiments are not limited thereto.

Referring to FIG. 6C, the first portion 432 of the pattern insulating layer 430 may be partially removed to form the pattern portions PTP respectively corresponding to the unit areas DA.

In an embodiment, the first portion 432 of the pattern insulating layer 430 may be partially removed by a photolithography process and an etching process to form the plurality of slits SL. For example, the slits SL may be formed by a dry etching process using a first etching gas that selectively etches the pattern insulating layer 430.

Referring to FIG. 6D, the second portion 434 of the pattern insulating layer 430 may be partially removed to form the second openings OP2 respectively corresponding to the unit areas DA, and the second portion 424 of the cover insulating layer 420 may be partially removed to form the third openings OP3 respectively corresponding to the unit areas DA.

In an embodiment, the second portion 434 of the pattern insulating layer 430 may be partially removed by a photolithography process and an etching process to form the second openings OP2, and the second portion 424 of the cover insulating layer 420 may be partially removed in the same process to form the third openings OP3. For example, the second openings OP2 and the third openings OP3 may be formed substantially simultaneously (e.g., may be formed concurrently) by a dry etching process using a second etching gas that etches both the pattern insulating layer 430 and the cover insulating layer 420.

Referring to FIG. 6E, the base layer 410 may be partially removed to form the first openings OP1 respectively corresponding to the unit areas DA.

In an embodiment, the base layer 410 may be partially removed by a photolithography process and an etching process to form the first openings OP1. For example, the first openings OP1 may be formed by a wet etching process using an etchant that selectively etches the base layer 410. For example, when the base layer 410 includes silicon, the base layer 410 may be etched by using tetramethylammonium hydroxide (“TMAH”). In such an embodiment, because the reinforcement pattern 450 is covered by the second portion 434 of the pattern insulating layer 430, the reinforcement pattern 450 may be prevented from being damaged by TMAH.

As illustrated in FIG. 3, the first portion 422 of the cover insulating layer 420 may be partially removed to form the fourth openings OP4 respectively corresponding to the unit areas DA, thereby manufacturing the mask 40.

In an embodiment, the first portion 422 of the cover insulating layer 420 may be partially removed by a photolithography process and an etching process to form the fourth openings OP4. For example, the fourth openings OP4 may be formed by a wet etching process using an etchant that selectively etches the cover insulating layer 420.

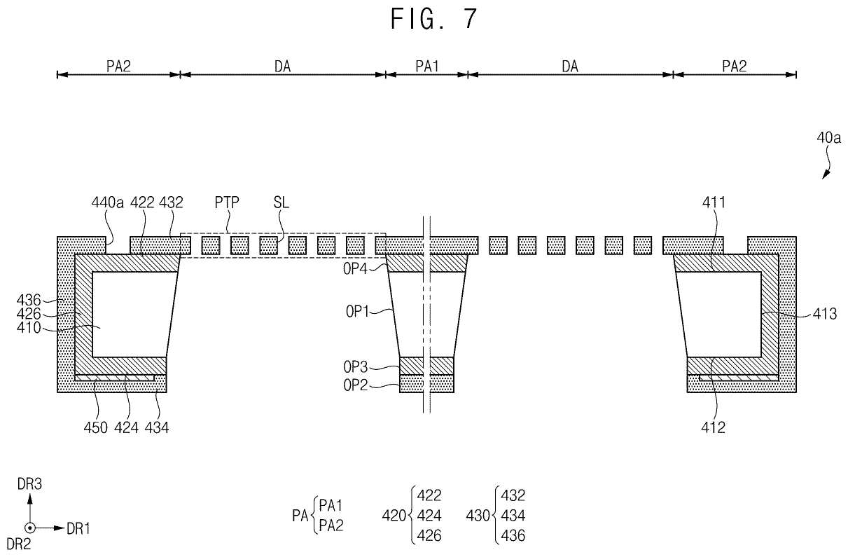

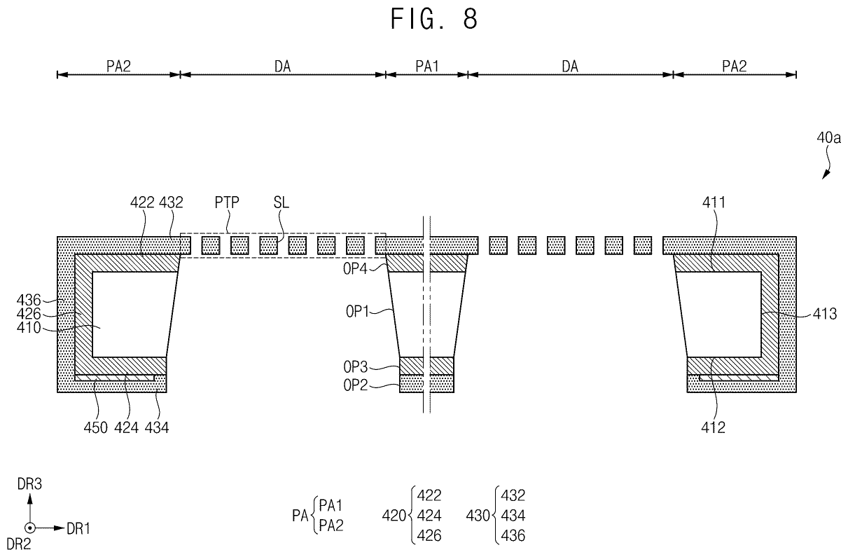

FIGS. 7 and 8 are cross-sectional views illustrating a mask according to an embodiment.

FIG. 7 may correspond to FIG. 3, and FIG. 8 may correspond to FIG. 4. A mask 40a shown in FIGS. 7 and 8 may be similar to the mask 40 described above with reference to FIGS. 2 to 4, except that the alignment pattern is omitted and an alignment opening 440a is defined therein. Hereinafter, the mask 40a will be described focusing on the differences from the mask 40 shown in FIGS. 2 to 4, and repeated descriptions therebetween may be omitted or simplified.

Referring to FIGS. 7 and 8, in an embodiment, the first portion 432 of the pattern insulating layer 430 may define the alignment opening 440a. The alignment opening 440a may be defined in the second peripheral area PA2 on the first surface 411 of the base layer 410. The alignment opening 440a may be used to align the mask 40a and the substrate S (see, e.g., FIG. 1) with each other. In an embodiment, the alignment opening 440a may penetrate (e.g., may extend through) the first portion 432 of the pattern insulating layer 430 in the third direction DR3.

The reinforcement pattern 450 may be disposed in the peripheral area PA on the second surface 412 of the base layer 410. The reinforcement pattern 450 may be disposed in a portion of the peripheral area PA. The alignment opening 440a and the reinforcement pattern 450 may be positioned in opposite directions to each other with the base layer 410 and the cover insulating layer 420 interposed therebetween. In an embodiment, as illustrated in FIG. 7, the reinforcement pattern 450 may overlap the alignment opening 440a in a plan view.

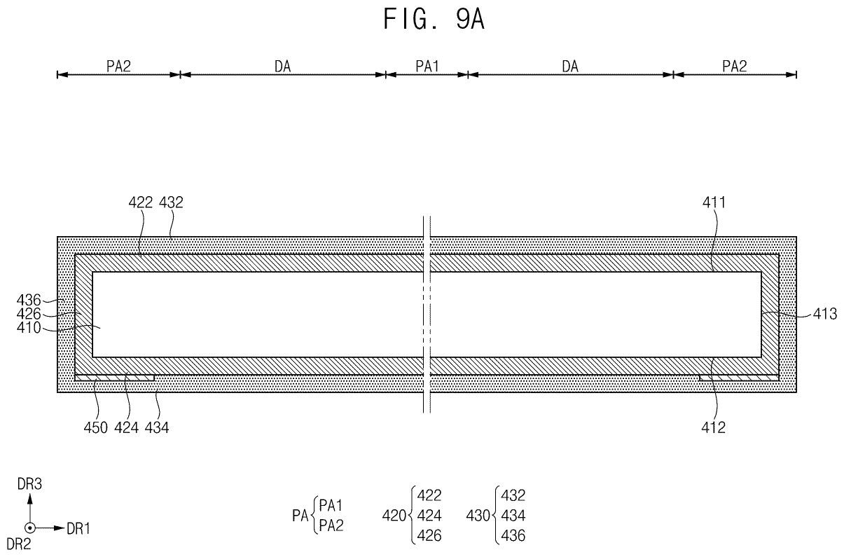

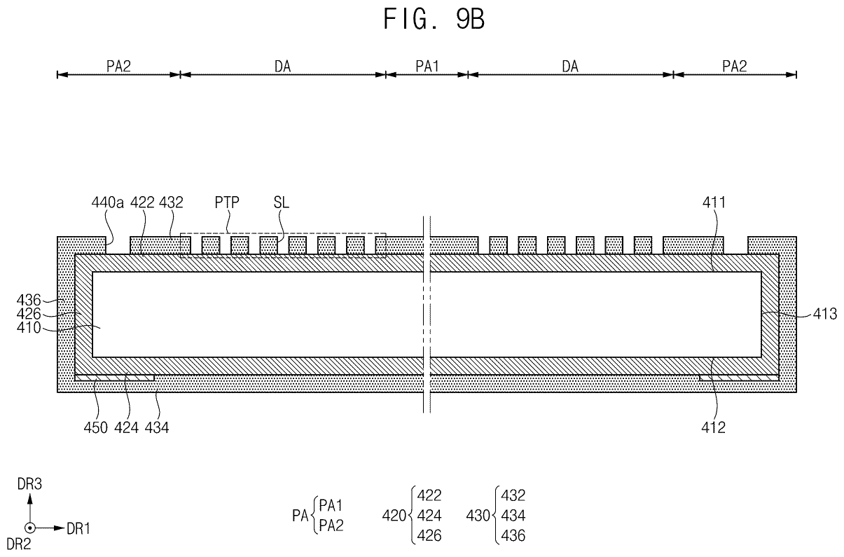

FIGS. 9A and 9B are cross-sectional views illustrating steps of a method for manufacturing a mask according to an embodiment.

Each of FIGS. 9A and 9B may correspond to the cross-sectional view of FIG. 7. FIGS. 9A and 9B may illustrate an example of a method for manufacturing the mask 40a described above with reference to FIGS. 7 and 8. Hereinafter, steps of the method for manufacturing the mask 40a will be described focusing on the differences from the method for manufacturing the mask 40 described above with reference to FIGS. 6A to 6E, and repeated descriptions therebetween may be omitted or simplified.

Referring to FIG. 9A, the cover insulating layer 420 may be formed on the base layer 410. The reinforcement pattern 450 may be formed on the lower surface of the second portion 424 of the cover insulating layer 420. The pattern insulating layer 430 may be formed on the cover insulating layer 420 and the reinforcement pattern 450. The second portion 434 of the pattern insulating layer 430 may cover the reinforcement pattern 450.

Referring to FIG. 9B, the first portion 432 of the pattern insulating layer 430 may be partially removed to form the pattern portions PTP and the alignment openings 440a.

In an embodiment, the first portion 432 of the pattern insulating layer 430 may be partially removed by a photolithography process and an etching process to form the plurality of slits SL and the alignment opening 440a. The slits SL may be formed in each of the unit areas DA, and the alignment opening 440a may be formed in the second peripheral area PA2. For example, the slits SL and the alignment opening 440a may be formed substantially simultaneously (e.g., may be formed concurrently) by a dry etching process using an etching gas that selectively etches the pattern insulating layer 430.

As illustrated in FIG. 7, the first to fourth openings OP1, OP2, OP3, and OP4 may be formed, thereby manufacturing the mask 40a.

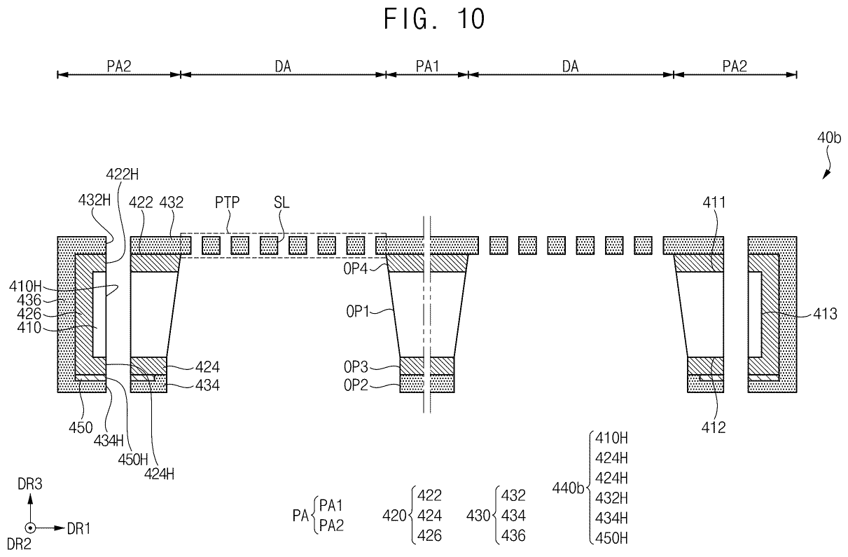

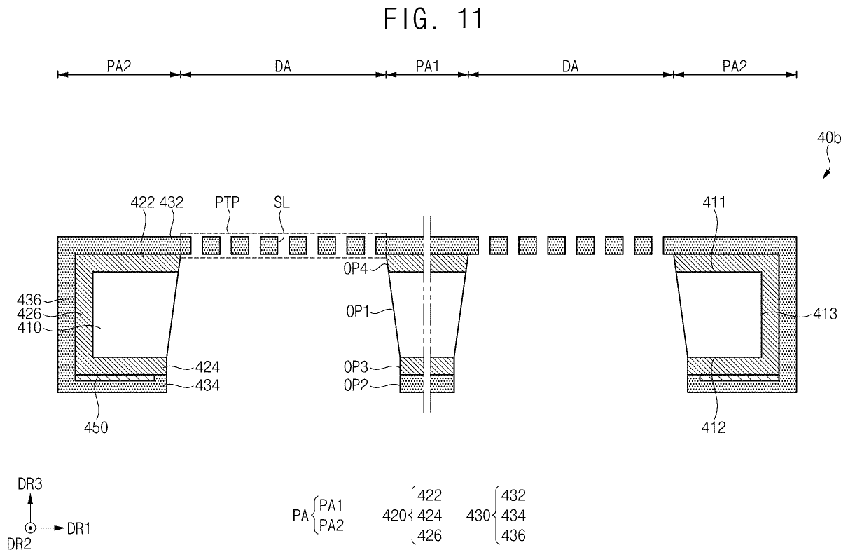

FIGS. 10 and 11 are cross-sectional views illustrating a mask according to an embodiment.

FIG. 10 may correspond to FIG. 3, and FIG. 11 may correspond to FIG. 4. A mask 40b shown in FIGS. 10 and 11 may be similar to the mask 40 described above with reference to FIGS. 2 to 4, except that the alignment pattern is omitted and an alignment opening 440b is defined. Hereinafter, the mask 40b will be described focusing on the differences from the mask 40 shown in FIGS. 2 to 4, and repeated descriptions therebetween may be omitted or simplified.

Referring to FIGS. 10 and 11, in an embodiment, the mask 40b may define the alignment opening 440b. The alignment opening 440b may be defined in the second peripheral area PA2. The alignment opening 440b may be used to align the mask 40b and the substrate S (see, e.g., FIG. 1) with each other. In an embodiment, the alignment opening 440b may penetrate (e.g., may extend through) the base layer 410, the cover insulating layer 420, the pattern insulating layer 430, and the reinforcement pattern 450 in the third direction DR3.

The base layer 410 may define a first through hole 410H in the second peripheral area PA2. The first through hole 410H may penetrate the base layer 410 in the third direction DR3.

The first portion 422 of the cover insulating layer 420 may define a second through hole 422H in the second peripheral area PA2. The second through hole 422H may penetrate the first portion 422 of the cover insulating layer 420 in the third direction DR3.

The second portion 424 of the cover insulating layer 420 may define a third through hole 424H in the second peripheral area PA2. The third through hole 424H may penetrate the second portion 424 of the cover insulating layer 420 in the third direction DR3.

The reinforcement pattern 450 may define a fourth through hole 450H in the second peripheral area PA2. The fourth through hole 450H may penetrate the reinforcement pattern 450 in the third direction DR3.

The first portion 432 of the pattern insulating layer 430 may define a fifth through hole 432H in the second peripheral area PA2. The fifth through hole 432H may penetrate the first portion 432 of the pattern insulating layer 430 in the third direction DR3.

The second portion 434 of the pattern insulating layer 430 may define a sixth through hole 434H in the second peripheral area PA2. The sixth through hole 434H may penetrate the second portion 434 of the pattern insulating layer 430 in the third direction DR3.

As illustrated in FIG. 10, the first to sixth through holes 410H, 422H, 424H, 450H, 432H, and 434H may be connected to each other (e.g., may be aligned with each other) in the third direction DR3 to form the alignment opening 440b. The alignment opening 440b may penetrate the mask 40b in the third direction DR3.

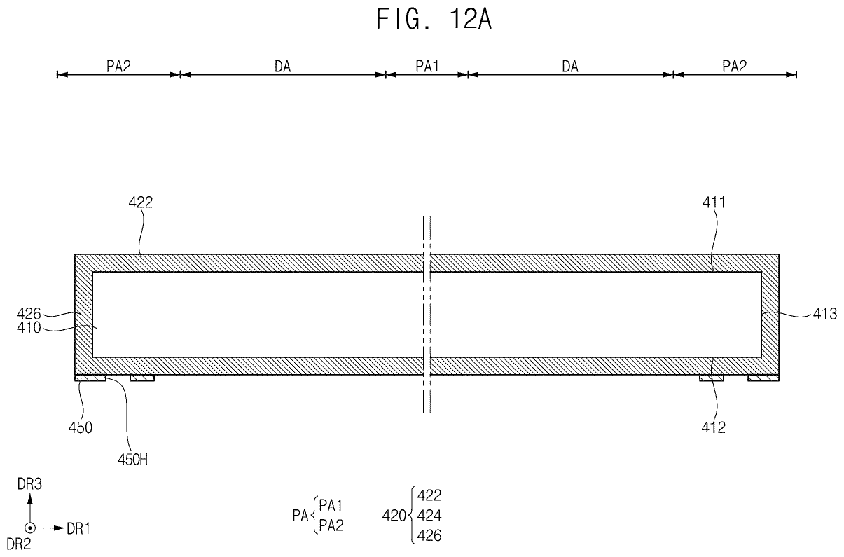

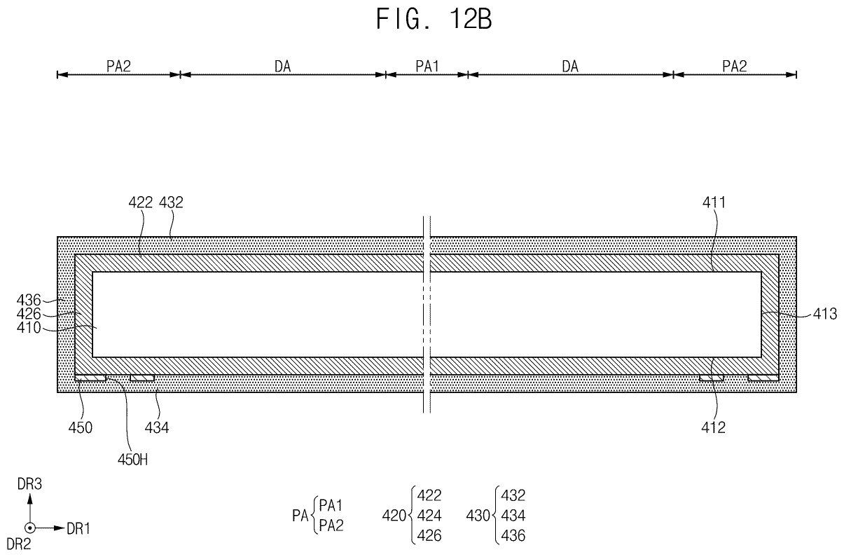

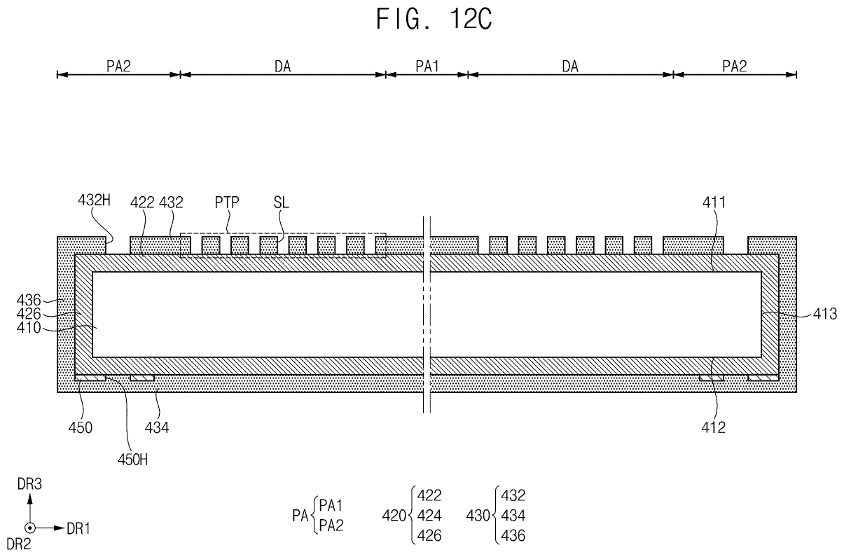

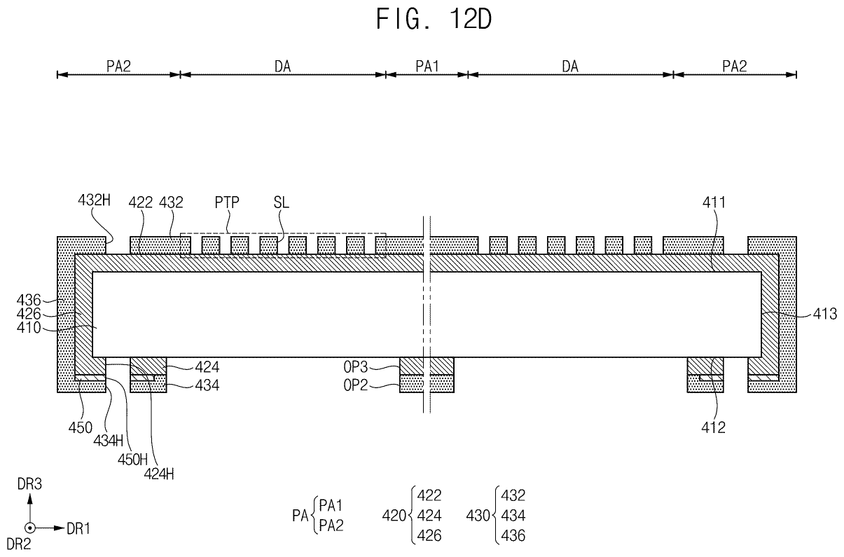

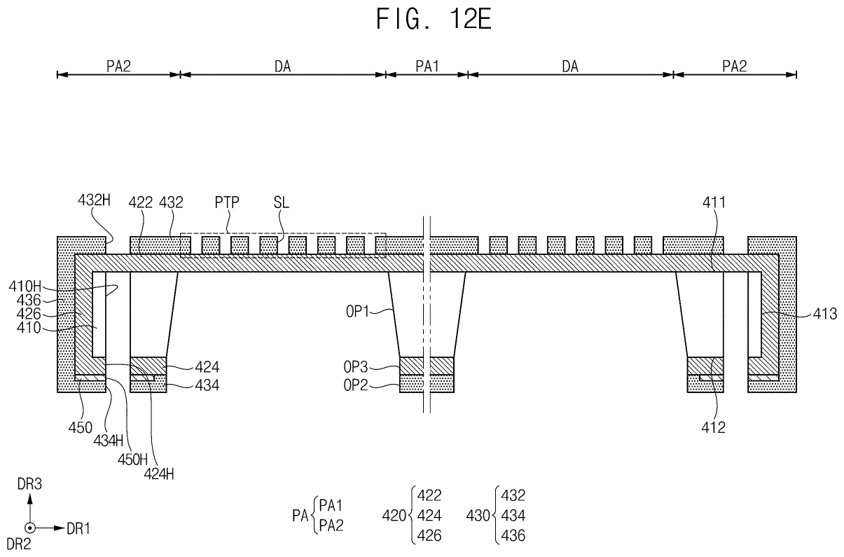

FIGS. 12A to 12E are cross-sectional views illustrating steps of a method for manufacturing a mask according to an embodiment.

Each of FIGS. 12A to 12E may correspond to the cross-sectional view of FIG. 10. FIGS. 12A to 12E may illustrate steps of a method for manufacturing the mask 40b described above with reference to FIGS. 10 and 11. Hereinafter, the method for manufacturing the mask 40b will be described focusing on the differences from the method for manufacturing the mask 40 described above with reference to FIGS. 6A to 6E, and repeated descriptions therebetween may be omitted or simplified.

Referring to FIG. 12A, the cover insulating layer 420 may be formed on the base layer 410. The reinforcement pattern 450 defining the fourth through hole 450H may be formed on the lower surface of the second portion 424 of the cover insulating layer 420. For example, after depositing a thin film on the lower surface of the second portion 424 of the cover insulating layer 420, the thin film may be partially removed by a photolithography process and an etching process to form the reinforcement pattern 450 defining the fourth through hole 450H.

Referring to FIG. 12B, the pattern insulating layer 430 may be formed on the cover insulating layer 420 and the reinforcement pattern 450. The second portion 434 of the pattern insulating layer 430 may cover the reinforcement pattern 450.

Referring to FIG. 12C, the first portion 432 of the pattern insulating layer 430 may be partially removed to form the pattern portions PTP and the fifth through hole 432H.

In an embodiment, the first portion 432 of the pattern insulating layer 430 may be partially removed by a photolithography process and an etching process to form the plurality of slits SL and the fifth through hole 432H. The slits SL may be formed in each of the unit areas DA, and the fifth through hole 432H may be formed in the second peripheral area PA2. For example, the slits SL and the fifth through hole 432H may be formed substantially simultaneously (e.g., may be formed concurrently) by a dry etching process using a first etching gas that selectively etches the pattern insulating layer 430.

Referring to FIG. 12D, the second portion 434 of the pattern insulating layer 430 may be partially removed to form the second openings OP2 and the sixth through hole 434H, and the second portion 424 of the cover insulating layer 420 may be partially removed to form the third openings OP3 and the third through hole 424H.

In an embodiment, the second portion 434 of the pattern insulating layer 430 may be partially removed by a photolithography process and an etching process to form the second openings OP2 and the sixth through hole 434H, and the second portion 424 of the cover insulating layer 420 may be partially removed in the same process to form the third openings OP3 and the third through hole 424H. The second openings OP2 and the third openings OP3 may be formed to correspond to the unit areas DA, and the third through hole 424H and the sixth through hole 434H may be formed in the second peripheral area PA2. For example, the second openings OP2, the third openings OP3, the third through hole 424H, and the sixth through hole 434H may be formed substantially simultaneously (e.g., may be formed concurrently) by a dry etching process using a second etching gas that etches both the pattern insulating layer 430 and the cover insulating layer 420.

Referring to FIG. 12E, the base layer 410 may be partially removed to form the first openings OP1 and the first through hole 410H.

In an embodiment, the base layer 410 may be partially removed by a photolithography process and an etching process to form the first openings OP1 and the first through hole 410H. The first openings OP1 may be formed to respectively correspond to the unit areas DA, and the first through hole 410H may be formed in the second peripheral area PA2. For example, the first openings OP1 and the first through hole 410H may be formed substantially simultaneously (e.g., may be formed concurrently) by a wet etching process using an etchant that selectively etches the base layer 410.

As illustrated in FIG. 10, the first portion 422 of the cover insulating layer 420 may be partially removed to form the fourth openings OP4 and the second through hole 422H.

In an embodiment, the first portion 422 of the cover insulating layer 420 may be partially removed by a photolithography process and an etching process to form the fourth openings OP4 and the second through hole 422H. The fourth openings OP4 may be formed respectively corresponding to the unit areas DA, and the second through hole 422H may be formed in the second peripheral area PA2. For example, the fourth openings OP4 and second through hole 422H may be formed substantially simultaneously (e.g., may be formed concurrently) by a wet etching process using an etchant that selectively etches the cover insulating layer 420.

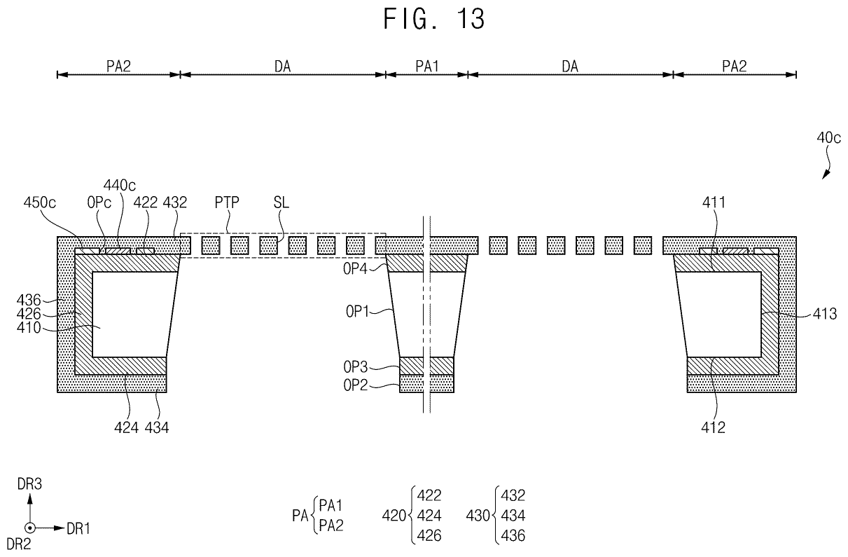

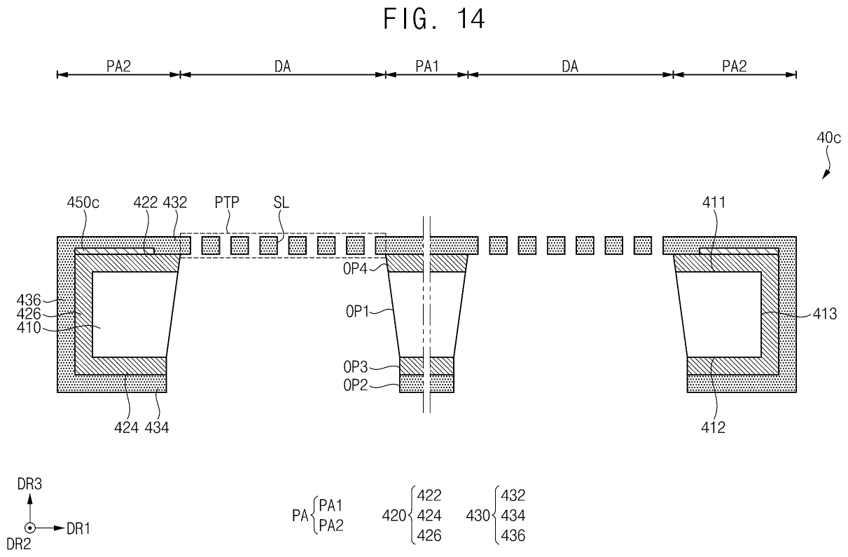

FIGS. 13 and 14 are cross-sectional views illustrating a mask according to an embodiment.

FIG. 13 may correspond to FIG. 3, and FIG. 14 may correspond to FIG. 4. A mask 40c shown in FIGS. 13 and 14 may be similar to the mask 40 described above with reference to FIGS. 2 to 4, except that a reinforcement pattern 450c is disposed on the first surface 411 of the base layer 410. Hereinafter, the mask 40c will be described focusing on the differences from the mask 40 shown in FIGS. 2 to 4, and repeated descriptions therebetween may be omitted or simplified.

In an embodiment, the pattern insulating layer 430 may include a material having a thermal expansion coefficient that is greater than the thermal expansion coefficient of the base layer 410.

An alignment pattern 440c may be disposed in the second peripheral area PA2 on the first surface 411 of the base layer 410. The alignment pattern 440c may be used to align the mask 40c and the substrate S (see, e.g., FIG. 1) with each other.

The reinforcement pattern 450c may include a material having a thermal expansion coefficient that is less than the thermal expansion coefficient of the base layer 410. For example, the reinforcement pattern 450c may include an Invar alloy (a nickel-iron alloy), an insulating material, or the like.

Tensile stress may be induced in the first portion 432 of the pattern insulating layer 430, and compressive stress may be induced in the reinforcement pattern 450c. The first portion 432 of the pattern insulating layer 430 and the reinforcement pattern 450c may be disposed on the first surface 411 of the base layer 410. For example, the first portion 432 of the pattern insulating layer 430 and the reinforcement pattern 450c may both be positioned above the base layer 410. Because the reinforcement pattern 450c in which the compressive stress is induced is positioned in the same direction as the first portion 432 of the pattern insulating layer 430 with respect to the base layer 410, the tensile stress induced in the first portion 432 of the pattern insulating layer 430 may be more effectively offset. Therefore, warpage of the mask 40c may be reduced, and precise patterning may be possible.

In an embodiment, as illustrated in FIG. 13, the alignment pattern 440c and the reinforcement pattern 450c may be disposed on the same layer and may include the same material. The alignment pattern 440c and the reinforcement pattern 450c may be disposed between the cover insulating layer 420 and the pattern insulating layer 430. The alignment pattern 440c and the reinforcement pattern 450c may be disposed between the first portion 422 of the cover insulating layer 420 and the first portion 432 of the pattern insulating layer 430. For example, the alignment pattern 440c and the reinforcement pattern 450c may be disposed on the upper surface of the first portion 422 of the cover insulating layer 420 and may be covered by the first portion 432 of the pattern insulating layer 430. A thickness of the first portion 432 of the pattern insulating layer 430 may be greater than each of a thickness of the alignment pattern 440c and a thickness of the reinforcement pattern 450c.

The alignment pattern 440c and the reinforcement pattern 450c may be spaced apart from each other. The reinforcement pattern 450c may have various planar shapes to effectively offset the tensile stress induced in the first portion 432 of the pattern insulating layer 430. In an embodiment, the reinforcement pattern 450c may be primarily disposed in an outer area of the mask 40c.

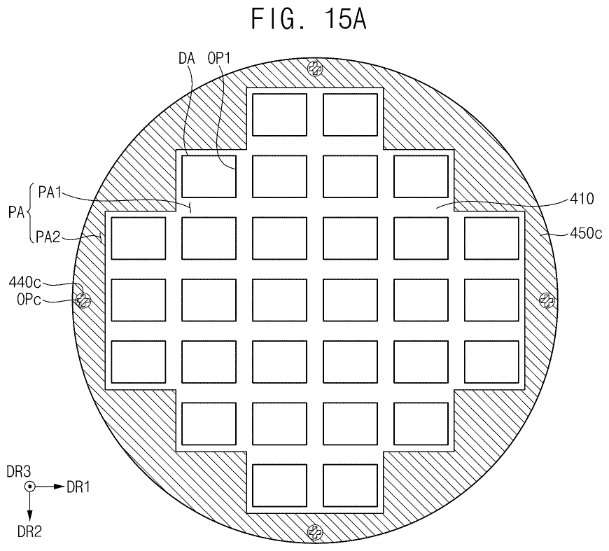

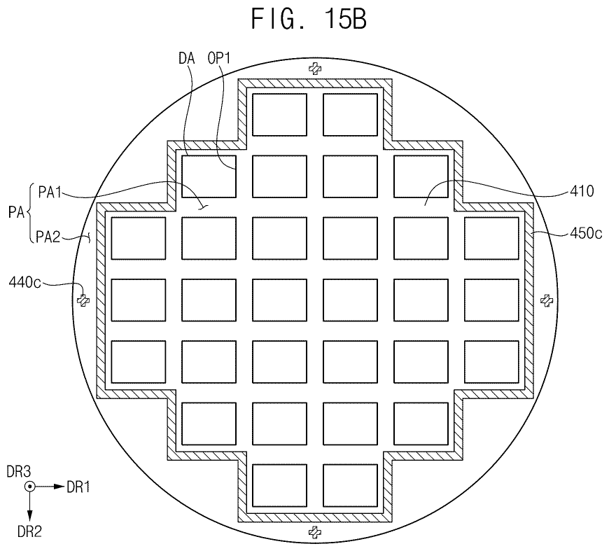

FIGS. 15A and 15B are top views illustrating some components of a mask according to an embodiment. For example, each of FIGS. 15A and 15B may illustrate the base layer 410, the alignment pattern 440c, and the reinforcement pattern 450c.

In an embodiment, as illustrated in FIG. 15A, the reinforcement pattern 450c may be disposed in the second peripheral area PA2 and may have a shape surrounding the unit areas DA in a plan view. The reinforcement pattern 450c may have a ring shape in a plan view.

In a plan view, the alignment pattern 440c may be disposed inside the reinforcement pattern 450c. For example, as illustrated in FIGS. 13 and 15A, the reinforcement pattern 450c may define an opening OPc overlapping the alignment pattern 440c. In a plan view, the alignment pattern 440c may be disposed in the opening OPc in the reinforcement pattern 450c. An inner side surface of the reinforcement pattern 450c that defines the opening OPc may be spaced apart from an outer side surface of the alignment pattern 440c. For example, in a plan view, the reinforcement pattern 450c may be spaced apart from the alignment pattern 440c and may surround the alignment pattern 440c.

In an embodiment, as illustrated in FIG. 15B, in a plan view, the alignment pattern 440c may be disposed outside the reinforcement pattern 450c. In such an embodiment, the reinforcement pattern 450c may not define an opening.

The shape of each of the alignment pattern 440c and the reinforcement pattern 450c illustrated in FIGS. 15A and 15B is an example, and embodiments are not limited thereto. In other embodiments, the shape and arrangement of each of the alignment pattern 440c and the reinforcement pattern 450c may be variously changed.

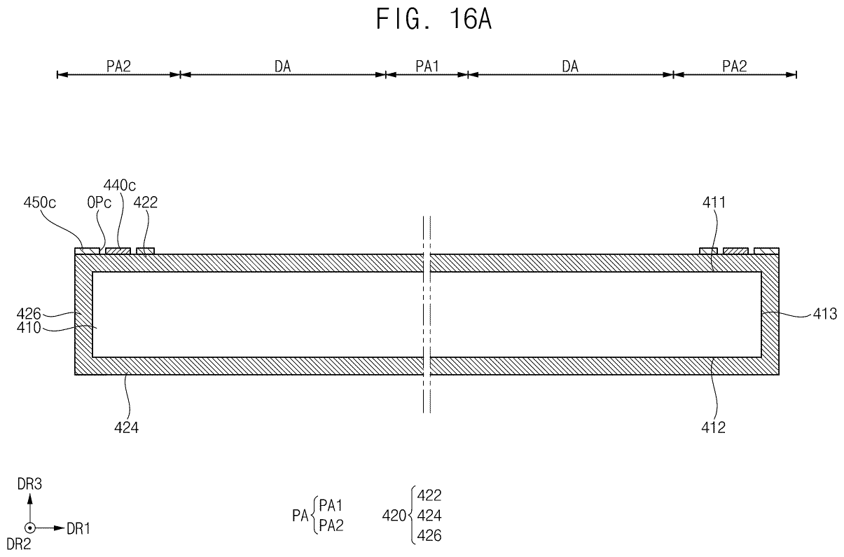

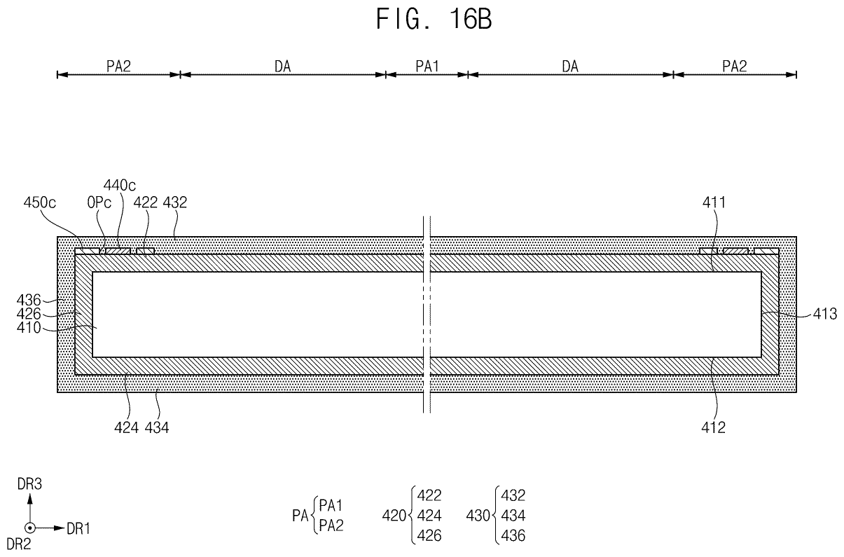

FIGS. 16A and 16B are cross-sectional views illustrating steps of a method for manufacturing a mask according to an embodiment.

Each of FIGS. 16A and 16B may correspond to the cross-sectional view of FIG. 13. FIGS. 16A and 16B may illustrate steps of a method for manufacturing the mask 40c described above with reference to FIGS. 13 and 14. Hereinafter, the method for manufacturing the mask 40c will be described focusing on the differences from the method for manufacturing the mask 40 described above with reference to FIGS. 6A to 6E, and repeated descriptions therebetween may be omitted or simplified.

Referring to FIG. 16A, the cover insulating layer 420 may be formed on the base layer 410. The alignment pattern 440c and the reinforcement pattern 450c may be formed on the upper surface of the first portion 422 of the cover insulating layer 420. For example, after depositing a thin film on the upper surface of the first portion 422 of the cover insulating layer 420, the thin film may be partially removed by a photolithography process and an etching process to form the alignment pattern 440c and the reinforcement pattern 450c substantially simultaneously (e.g., concurrently).

Referring to FIG. 16B, the pattern insulating layer 430 may be formed on the cover insulating layer 420, the alignment pattern 440c, and the reinforcement pattern 450c. The first portion 432 of the pattern insulating layer 430 may cover the alignment pattern 440c and the reinforcement pattern 450c.

As illustrated in FIG. 13, the slits SL and the first to fourth openings OP1, OP2, OP3, and OP4 may be formed, thereby manufacturing the mask 40c.

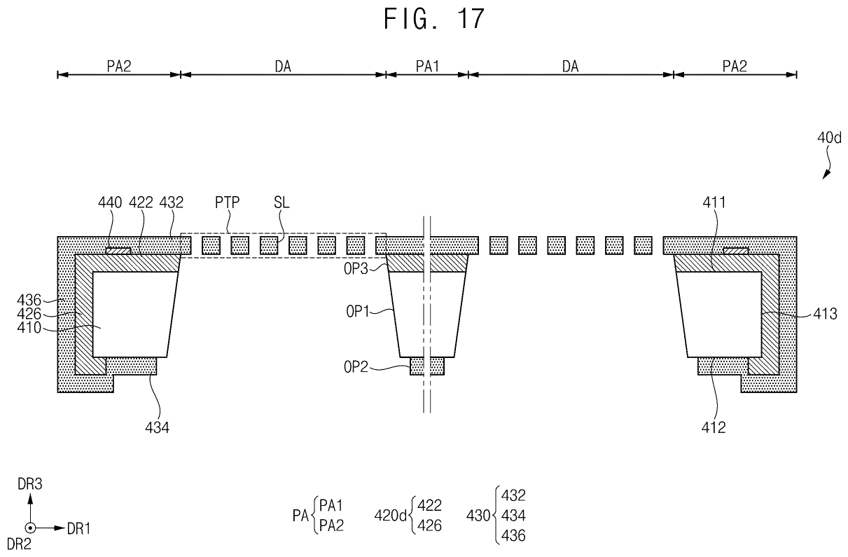

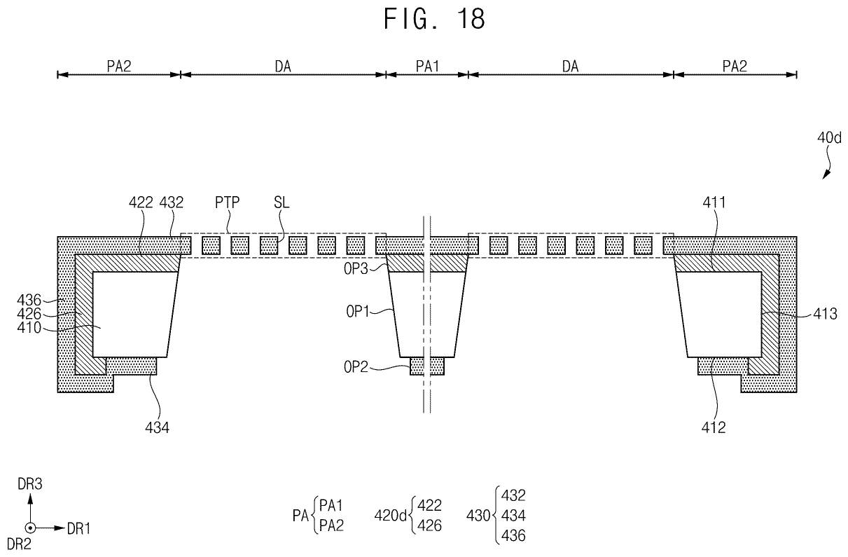

FIGS. 17 and 18 are cross-sectional views illustrating a mask according to an embodiment.

FIG. 17 may correspond to FIG. 3, and FIG. 18 may correspond to FIG. 4. A mask 40d shown in FIGS. 17 and 18 may be similar to the mask 40 described above with reference to FIGS. 2 to 4, except that the reinforcement pattern is omitted and a cover insulating layer 420d is not disposed below the base layer 410. Hereinafter, the mask 40d will be described focusing on the differences from the mask 40 shown in FIGS. 2 to 4, and repeated descriptions therebetween may be omitted or simplified.

The cover insulating layer 420d may be disposed between the base layer 410 and the pattern insulating layer 430. The cover insulating layer 420d may cover a portion of the base layer 410. For example, as illustrated in FIGS. 17 and 18, the cover insulating layer 420d may cover the first surface 411 and the outer side surface 413 of the base layer 410.

In an embodiment, the cover insulating layer 420d may include the first portion 422 disposed on the first surface 411 of the base layer 410 and the third portion 426 disposed on the outer side surface 413 of the base layer 410. The cover insulating layer 420d may not cover at least a portion of the second surface 412 of the base layer 410. The cover insulating layer 420d may not cover most of the second surface 412 of the base layer 410.

In the first peripheral area PA1, while the cover insulating layer 420d may be disposed on the first surface 411 of the base layer 410, the cover insulating layer 420d may not be disposed on the second surface 412 of the base layer 410. In the first peripheral area PA1, the first surface 411 of the base layer 410 may contact the first portion 422 of the cover insulating layer 420d, and the second surface 412 of the base layer 410 may contact the second portion 434 of the pattern insulating layer 430.

The pattern insulating layer 430 may cover at least a portion of the cover insulating layer 420d. In addition, the pattern insulating layer 430 may further cover at least a portion of the second surface 412 of the base layer 410 that is not covered by the cover insulating layer 420d.

In an embodiment, the pattern insulating layer 430 may include the first portion 432 disposed on the first surface 411 of the base layer 410, the second portion 434 disposed on the second surface 412 of the base layer 410, and the third portion 436 disposed on the outer side surface 413 of the base layer 410.

The first portion 432 of the pattern insulating layer 430 may include the pattern portions PTP respectively corresponding to the unit areas DA. The first portion 422 of the cover insulating layer 420d may be disposed between the base layer 410 and the first portion 432 of the pattern insulating layer 430.

The second portion 434 of the pattern insulating layer 430 may cover at least a portion of the second surface 412 of the base layer 410 that is not covered by the cover insulating layer 420d.

Another layer may not be disposed below the pattern portion PTP. The base layer 410 may define the first openings OP1 respectively corresponding to the unit areas DA. The second portion 434 of the pattern insulating layer 430 may define the second openings OP2 respectively corresponding to the unit areas DA. The first portion 422 of the cover insulating layer 420d may define the third openings OP3 respectively corresponding to the unit areas DA.

In an embodiment, in a plan view, a size of each of the second openings OP2 may be greater than a size of corresponding one of the first openings OP1. As illustrated in FIGS. 16 and 17, the second portion 434 of the pattern insulating layer 430 may not cover a portion of the second surface 412 of the base layer 410 and may expose the portion of the second surface 412 of the base layer 410.

Each of the cover insulating layer 420d and the pattern insulating layer 430 may include a different material than the base layer 410. In an embodiment, the cover insulating layer 420d may include a material having a thermal expansion coefficient less than the thermal expansion coefficient of the base layer 410, and the pattern insulating layer 430 may include a material having a thermal expansion coefficient that is greater than the thermal expansion coefficient of the base layer 410. For example, the base layer 410 may include silicon, the cover insulating layer 420d may include silicon oxide, and the pattern insulating layer 430 may include silicon nitride.

The compressive stress may be induced in the cover insulating layer 420d, and the tensile stress may be induced in the pattern insulating layer 430. Because the cover insulating layer 420d is disposed only on the first surface 411 of the base layer 410 and is not disposed on the second surface 412 of the base layer 410, the tensile stress induced in the first portion 432 of the pattern insulating layer 430 may be effectively offset by the compressive stress induced in the cover insulating layer 420d. Therefore, warpage of the mask 40d may be reduced, and precise patterning may be possible.

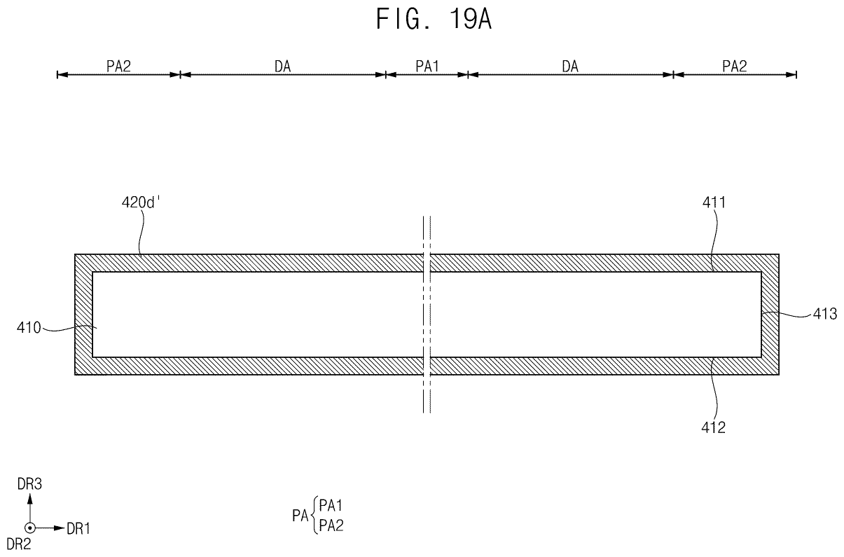

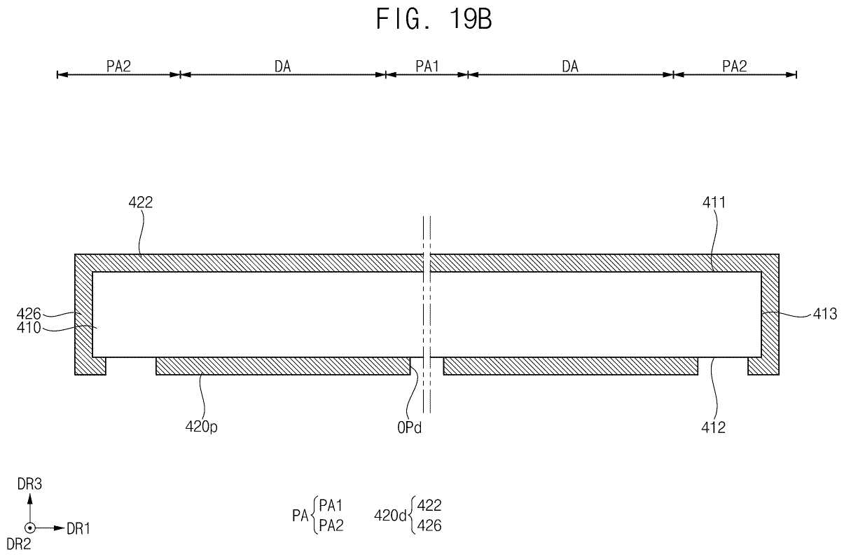

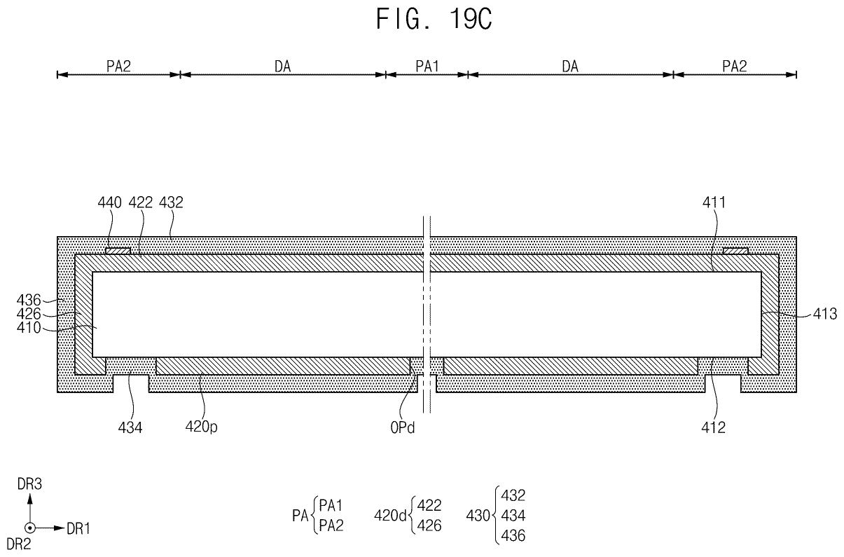

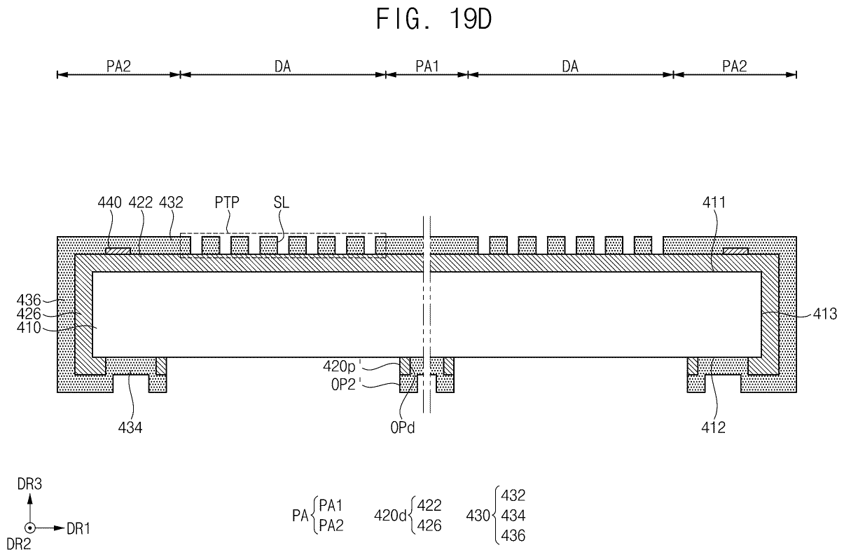

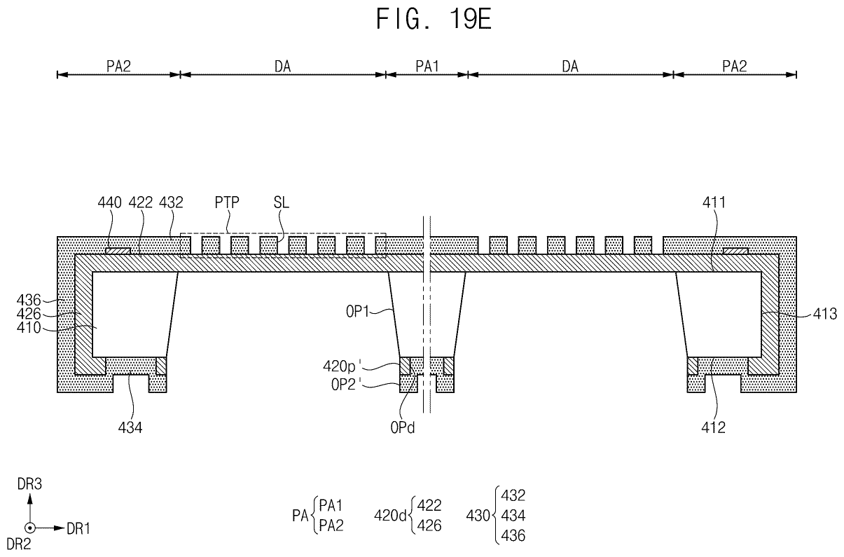

FIGS. 19A to 19E are cross-sectional views illustrating a method for manufacturing a mask according to an embodiment.

Each of FIGS. 19A to 19E may correspond to the cross-sectional view of FIG. 17. FIGS. 19A to 19E may illustrate steps of a method for manufacturing the mask 40d described above with reference to FIGS. 17 and 18. Hereinafter, the method for manufacturing the mask 40d will be described focusing on the differences from the method for manufacturing the mask 40 described above with respect to FIGS. 6A to 6E, and repeated descriptions therebetween may be omitted or simplified.

Referring to FIG. 19A, an insulating layer 420d′ may be formed on the base layer 410. The insulating layer 420d′ may be formed to cover the entire base layer 410. For example, the insulating layer 420d′ may be formed to cover the first surface 411, the second surface 412, and the outer side surface 413 of the base layer 410. In an embodiment, the insulating layer 420d′ may be formed by oxidizing the base layer 410. Referring to FIG. 19B, the insulating layer 420d′ may be partially removed to form the cover insulating layer 420d and insulating patterns 420p. The insulating layer 420d′ may be partially removed on the second surface 412 of the base layer 410 to form an opening OPd corresponding to the peripheral area PA. For example, the opening OPd may have a grid shape in a plan view. Therefore, the insulating patterns 420p, which are spaced apart from each other, may be formed on the second surface 412 of the base layer 410. The cover insulating layer 420d may cover the first surface 411 and the outer side surface 413 of the base layer 410.

The insulating patterns 420p may respectively overlap the unit areas DA. In an embodiment, a width of the opening OPd may be less than a width of the first peripheral area PA1. For example, in a plan view, a size of each of the insulating patterns 420p may be greater than a size of corresponding one of the unit areas DA, and each of the insulating patterns 420p may further overlap a portion of the adjacent peripheral area PA.

Referring to FIG. 19C, the alignment pattern 440 may be formed on the upper surface of the first portion 422 of the cover insulating layer 420d, and the pattern insulating layer 430 may be formed on the cover insulating layer 420d, the insulating patterns 420p, and the alignment pattern 440. The first portion 432 of the pattern insulating layer 430 may cover the alignment pattern 440. The second portion 434 of the pattern insulating layer 430 may cover the second surface 412 of the base layer 410 exposed by the insulating patterns 420p and the opening OPd.

Referring further to FIG. 19D, the first portion 432 of the pattern insulating layer 430 may be partially removed to form the slits SL.

The second portion 434 of the pattern insulating layer 430 may be partially removed to form preliminary second openings OP2′ and to remove the insulating patterns 420p.

In an embodiment, the second portion 434 of the pattern insulating layer 430 may be partially removed by a photolithography process and an etching process to form the preliminary second openings OP2′, and the insulating patterns 420p may be removed in the same process. In an embodiment, as illustrated in FIG. 19D, each of the insulating patterns 420p may not be completely removed (e.g., may be only partially removed), a portion 420p′ of the insulating patterns 420p overlapping the peripheral area PA of each of the insulating patterns 420p may remain, thereby forming each of remaining insulating patterns 420p′ having a ring shape in a plan view.

Referring to FIG. 19E, the base layer 410 may be partially removed to form the first openings OP1 respectively corresponding to the unit areas DA.

As illustrated in FIG. 17, the first portion 422 of the cover insulating layer 420d may be partially removed to form the third openings OP3. At this time, the remaining insulating patterns 420p′ on the second surface 412 of the base layer 410 and portions of the second portion 434 of the pattern insulating layer 430 that are positioned below the remaining insulating patterns 420p′ may be removed together.

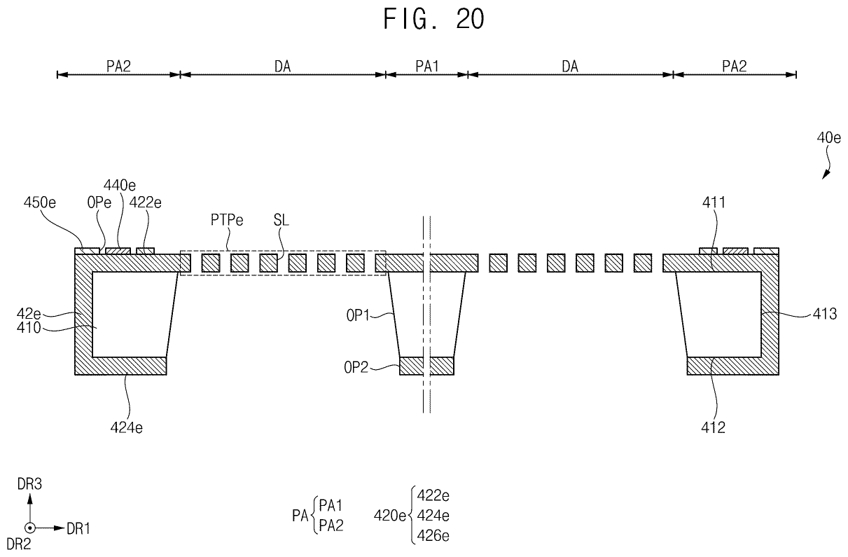

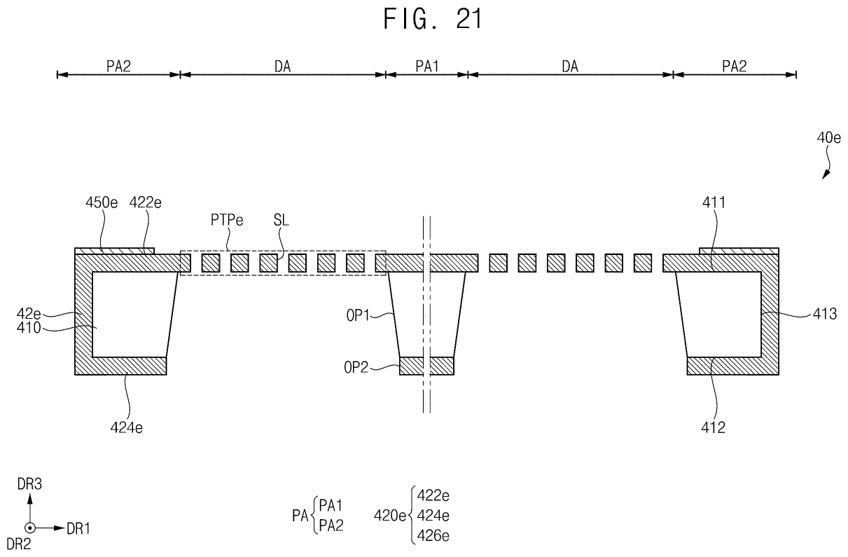

FIGS. 20 and 21 are cross-sectional views illustrating a mask according to an embodiment.

FIG. 20 may correspond to FIG. 3, and FIG. 21 may correspond to FIG. 4. A mask 40e shown in FIGS. 20 and 21 may be similar to the mask 40 described above with reference to FIGS. 2 to 4, except that a reinforcement pattern 450e is disposed on the first surface 411 of the base layer 410. Hereinafter, the mask 40e will be described focusing on the differences from the mask 40 shown in FIGS. 2 to 4, and repeated descriptions therebetween may be omitted or simplified.

In an embodiment, the pattern insulating layer 420e may cover at least a portion of the base layer 410. For example, as illustrated in FIGS. 20 and 21, the pattern insulating layer 420e may cover the first surface 411, the second surface 412, and the outer side surface 413 of the base layer 410.

In an embodiment, the pattern insulating layer 420e may include a first portion 422e disposed on the first surface 411 of the base layer 410, a second portion 424e disposed on the second surface 412 of the base layer 410, and a third portion 426e disposed on the outer side surface 413 of the base layer 410. The first portion 422e and the second portion 424e of the pattern insulating layer 420e may be positioned in opposite directions to each other with the base layer 410 interposed therebetween. For example, the first to third portions 422e, 424e, and 426e of the pattern insulating layer 420e may be connected to each other.

The first portion 422e of the pattern insulating layer 420e may contact the first surface 411 of the base layer 410. The second portion 424e of the pattern insulating layer 420e may contact the second surface 412 of the base layer 410. The third portion 426e of the pattern insulating layer 420e may contact the outer side surface 413 of the base layer 410.

The pattern insulating layer 420e may include a different material than the base layer 410. In an embodiment, the pattern insulating layer 420e may include a material having a thermal expansion coefficient that is less than a thermal expansion coefficient of the base layer 410. For example, the pattern insulating layer 420e may include silicon oxide, but this is an example and embodiments are not limited thereto. The pattern insulating layer 420e may include pattern portions PTPe

respectively corresponding to the unit areas DA on the first surface 411 of the base layer 410. The first portion 422e of the pattern insulating layer 420e may include the pattern portions PTPe. Each of the pattern portions PTPe may define the plurality of slits SL. Each of the slits SL may penetrate (e.g., may extend through) the first portion 422e of the pattern insulating layer 420e in the third direction DR3.

As illustrated in FIGS. 20 and 21, another layer may not be disposed below each of the pattern portions PTPe. The base layer 410 may define the first openings OP1 respectively corresponding to the unit areas DA. The second portion 424e of the pattern insulating layer 420e may define the second openings OP2 respectively corresponding to the unit areas DA.

While the first portion 422e of the pattern insulating layer 420e includes the pattern portions PTPe respectively corresponding to the unit areas DA, the second portion 424e of the pattern insulating layer 420e defines the second openings OP2 respectively corresponding to the unit areas DA so that, in a plan view, a size of the second portion 424e of the pattern insulating layer 420e may be less than a size of the first portion 422e of the pattern insulating layer 420e.

An alignment pattern 440e may be disposed in the second peripheral area PA2 on the first surface 411 of the base layer 410. The alignment pattern 440e may be used to align the mask 40e and the substrate S (see, e.g., FIG. 1) with each other.

The reinforcement pattern 450e may include a material having a thermal expansion coefficient that is greater than the thermal expansion coefficient of the base layer 410. For example, the reinforcement pattern 450e may include a metal or alloy, such as chromium, aluminum, tungsten, silver, or the like.

Compressive stress may be induced in the first portion 422e of the pattern insulating layer 420e, and tensile stress may be induced in the reinforcement pattern 450e. The first portion 422e of the pattern insulating layer 420e and the reinforcement pattern 450e may be disposed on the first surface 411 of the base layer 410. For example, the first portion 422e of the pattern insulating layer 420e and the reinforcement pattern 450e may both be positioned above the base layer 410. Because the reinforcement pattern 450e in which the tensile stress is induced is positioned in the same direction as the first portion 422e of the pattern insulating layer 420e with respect to the base layer 410, the compressive stress induced in the first portion 422e of the pattern insulating layer 420e may be more effectively offset. Therefore, warpage of the mask 40e may be reduced, and precise patterning may be possible.

In an embodiment, as illustrated in FIG. 20, the alignment pattern 440e and the reinforcement pattern 450e may be disposed on the same layer and may include the same material. The alignment pattern 440e and the reinforcement pattern 450e may be disposed on the upper surface of the first portion 422e of the pattern insulating layer 420e.

The alignment pattern 440e and the reinforcement pattern 450e may be spaced apart from each other. The reinforcement pattern 450e may have various planar shapes to effectively offset the tensile stress induced in the first portion 422e of the pattern insulating layer 420e (see, e.g., FIGS. 15A and 15B).

FIG. 22 is a cross-sectional view illustrating a display device according to an embodiment.

A display device 100 shown in FIG. 22 may be manufactured by using any one of the masks 40, 40a, 40b, 40c, 40d, and 40e described above.

Referring to FIG. 22, in an embodiment, the display device 100 may include a substrate 110, a buffer layer 120, pixels, insulating layers 132, 134, 136, and 138, a pixel defining layer 140, and an encapsulation layer 150. Each of the pixels may include a transistor TR, a capacitor CAP, and a light emitting element LED.

The substrate 110 may be an insulating substrate including or formed of a transparent material or a non-transparent material.

The buffer layer 120 may be disposed on the substrate 110. The buffer layer 120 may prevent or reduce impurities, such as oxygen or moisture, from penetrating into an upper portion of the substrate 110 through the substrate 110. The buffer layer 120 may include an inorganic material. In an embodiment, for example, the buffer layer 120 may include silicon oxide (SiOₓ), silicon nitride (SiNₓ), silicon oxynitride (SiOₓN_{y}), silicon oxycarbide (SiOₓC_{y}), silicon carbonitride (SiCₓN_{y}), aluminum oxide (AlOₓ), aluminum nitride (AlNₓ), tantalum oxide (TaOₓ), hafnium oxide (HfOₓ), zirconium oxide (ZrOₓ), titanium oxide (TiOₓ), or the like. These can be used alone or in a combination thereof. The buffer layer 120 may have a single-layer structure or a multi-layer structure including a plurality of insulating layers.

The transistor TR and the capacitor CAP may be disposed on the buffer layer 120. The transistor TR may include an active layer AL, a gate electrode GE, a source electrode SE, and a drain electrode DE.

The active layer AL may be disposed on the buffer layer 120. The active layer AL may include an oxide semiconductor, a silicon semiconductor, an organic semiconductor, or the like. In an embodiment, for example, the oxide semiconductor may include at least one selected from oxides of indium (In), gallium (Ga), tin (Sn), zirconium (Zr), vanadium (V), hafnium (Hf), cadmium (Cd), germanium (Ge), chromium (Cr), titanium (Ti), and zinc (Zn). The silicon semiconductor may include an amorphous silicon, a polycrystalline silicon, or the like. The active layer AL may have a source area, a drain area, and a channel area positioned between the source area and the drain area.

A first insulating layer 132 may be disposed on the active layer AL. The first insulating layer 132 may cover the active layer AL on the buffer layer 120. The first insulating layer 132 may include an inorganic insulating material.

The gate electrode GE may be disposed on the first insulating layer 132. The gate electrode GE may overlap the channel area of the active layer AL. The gate electrode GE may include a conductive material, such as a metal, an alloy, a conductive metal nitride, a conductive metal oxide, a transparent conductive material, or the like. In an embodiment, for example, the gate electrode GE may include gold (Au), silver (Ag), aluminum (AI), platinum (Pt), nickel (Ni), titanium (Ti), palladium (Pd), magnesium (Mg), calcium (Ca), lithium (Li), chromium (Cr), tantalum (Ta), tungsten (W), copper (Cu), molybdenum (Mo), scandium (Sc), neodymium (Nd), iridium (Ir), alloys containing aluminum, alloys containing silver, alloys containing copper, alloys containing molybdenum, aluminum nitride (AlNₓ), tungsten nitride (WNₓ), titanium nitride (TiNₓ), chromium nitride (CrNₓ), tantalum nitride (TaNₓ), strontium ruthenium oxide (SrRuOₓ), zinc oxide (ZnOₓ), indium tin oxide (ITO), tin oxide (SnOₓ), indium oxide (InOₓ), gallium oxide (GaOₓ), indium zinc oxide (IZO), or the like. These can be used alone or in a combination thereof. The gate electrode GE may have a single-layer structure or a multi-layer structure including a plurality of conductive layers.

A second insulating layer 134 may be disposed on the gate electrode GE. The second insulating layer 134 may cover the gate electrode GE on the first insulating layer 132. The second insulating layer 134 may include an inorganic insulating material.

A capacitor electrode CE may be disposed on the second insulating layer 134. The capacitor electrode CE may overlap the gate electrode GE. The gate electrode GE, the second insulating layer 134, and the capacitor electrode CE may form the capacitor CAP.

A third insulating layer 136 may be disposed on the capacitor electrode CPE. The third insulating layer 136 may cover the capacitor electrode CPE on the second insulating layer 134. The third insulating layer 136 may include an inorganic insulating material.

The source electrode SE and the drain electrode DE may be disposed on the third insulating layer 136. The source electrode SE and the drain electrode DE may be connected to the source area and the drain area of the active layer ACT, respectively. Each of the source electrode SE and the drain electrode DE may include a conductive material.

A fourth insulating layer 138 may be disposed on the source electrode SE and the drain electrode DE. The fourth insulating layer 138 may include an organic insulating material. In an embodiment, for example, the fourth insulating layer 138 may include a photoresist, a polyacryl-based resin, a polyimide-based resin, a polyamide-based resin, a siloxane-based resin, an acryl-based resin, an epoxy-based resin, or the like. These can be used alone or in a combination thereof.

A pixel electrode PE may be disposed on the fourth insulating layer 138. The pixel electrode PE may include a conductive material. The pixel electrode PE may be connected to the drain electrode DE through a contact hole (e.g., a contact opening) defined or formed in the fourth insulating layer 138. Accordingly, the pixel electrode PE may be electrically connected to the transistor TR.

The pixel defining layer 140 may be disposed on the pixel electrode PE. The pixel defining layer 140 may cover a peripheral portion of the pixel electrode PE and may define a pixel opening exposing a central portion of the pixel electrode PE. The pixel defining layer 140 may include an organic insulating material.

An emission layer EL may be disposed on the pixel electrode PE. The emission layer EL may be disposed in the pixel opening in the pixel defining layer 140. In an embodiment, the emission layer EL may include an organic light emitting material. The emission layer EL may be formed by deposition using any one of the masks 40, 40a, 40b, 40c, 40d, and 40e described above.

In an embodiment, the organic light emitting material may include a low molecular-weight organic compound or a high molecular-weight organic compound. Examples of the low molecular organic compound may include copper phthalocyanine, N,N′-diphenylbenzidine, tris-(8-hydroxyquinoline)aluminum, or the like. Examples of the high molecular-weight organic compound may include poly(3,4-ethylenedioxythiophene), polyaniline, poly-phenylenevinylene, polyfluorene, or the like. These can be used alone or in a combination thereof.

A common electrode CE may be disposed on the emission layer EL. The common electrode CE may also be disposed on the pixel defining layer 140. The common electrode CE may include a conductive material. The pixel electrode PE, the emission layer EL, and the common electrode CE may form the light emitting element LED.

The encapsulation layer 150 may be disposed on the common electrode CE. The encapsulation layer 150 may include at least one inorganic encapsulation layer and at least one organic encapsulation layer. In an embodiment, the encapsulation layer 150 may include a first inorganic encapsulation layer 152 disposed on the common electrode CE, an organic encapsulation layer 154 disposed on the first inorganic encapsulation layer 152, and a second inorganic encapsulation layer 156 disposed on the organic encapsulation layer 154. In addition, various functional layers, such as a touch sensing layer, a color filter layer, a light collecting layer, or the like may be additionally disposed on the encapsulation layer 150.

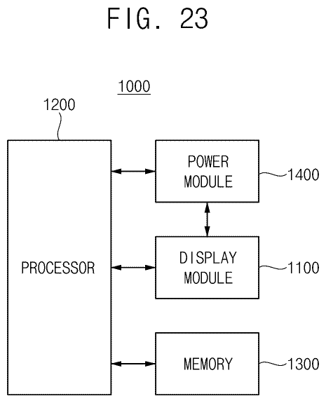

FIG. 23 is a block diagram describing an electronic device according to an embodiment.

Referring to FIG. 23, an electronic device 1000 may include a display module 1100, a processor 1200, a memory 1300, and a power module 1400.

A display device according to embodiments (e.g., the display device 100 shown in FIG. 22) may be applied to various electronic devices 1000. The electronic device 1000 may include the display device described above and may further include modules or devices with additional functions other than the display device.

The processor 1200 may include at least one of a central processing unit (“CPU”), an application processor (“AP”), a graphic processing unit (“GPU”), a communication processor (“CP”), an image signal processor (“ISP”), and a controller.

The memory 1300 may store data information necessary for the operation of the processor 1200 or the display module 1100. When the processor 1200 executes the application stored in the memory 1300, an image data signal and/or an input control signal may be transmitted to the display module 1100, and the display module 1100 may process the received signal and output image information through a display screen. In other words, the processor 1200 may provide the image data signal and/or the input control signal to the display device to control the display device.

The power module 1400 may include a power supply module, such as a power adapter or a battery device, and a power conversion module which converts the power supplied by the power supply module to generate power required for the operation of the electronic device 1000.

At least one of each component of the electronic device 1000 described above may be included in the display device according to the above-described embodiments. In addition, some of the individual modules functionally included in one module may be included in the display device, and other portions may be provided separately from the display device. For example, the display device may include the display module 1100, and the processor 1200, the memory 1300, and the power module 1400 may be provided in the form of other devices within the electronic device 1000 other than the display device.

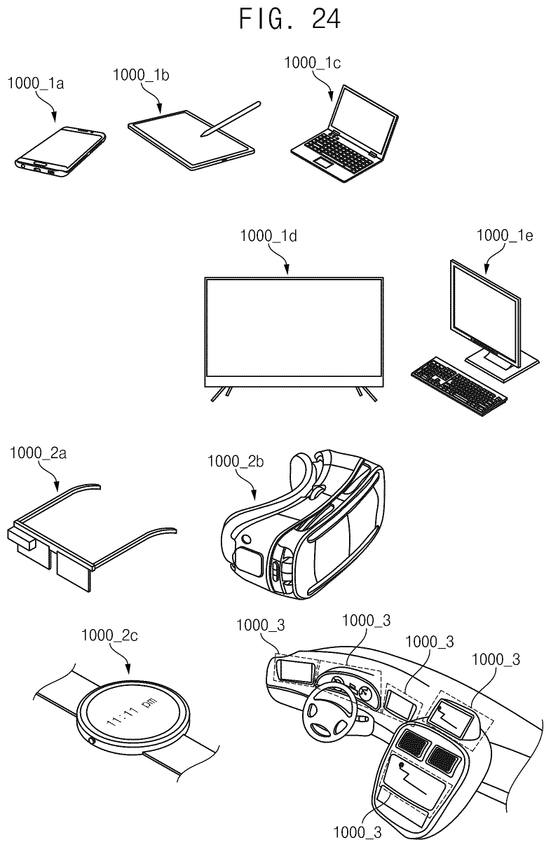

FIG. 24 is a schematic diagram showing electronic devices according to various embodiments.

Referring to FIG. 24, various electronic devices 1000 to which the display device according to the embodiments may be applied may include not only image display electronic devices, such as a smartphone 1000_1a, a tablet PC 1000_1b, a laptop 1000_1c, a TV 1000_1d, and a desktop monitor 1000_1e, but also wearable electronic devices including display modules, such as smart glasses 1000_2a, a head-mounted display 1000_2b, and a smart watch 1000_2c, automotive electronic devices 1000_3 including display modules, such as a dashboard of a car, a center fascia, a Center Information Display (“CID”) disposed on a dashboard, and a room mirror display, or the like.

The foregoing is illustrative of embodiments and is not to be construed as limiting thereof. Although a few embodiments have been described, those skilled in the art will readily appreciate that many modifications are possible in the described embodiments without materially departing from the scope and spirit of the present disclosure. Accordingly, all such modifications are intended to be included within the scope of the present disclosure as defined in the claims and their equivalents.

What is claimed is:

1. A mask for deposition comprising:
a plurality of unit areas spaced apart from each other and a peripheral area surrounding the unit areas in a plan view;
a base layer having a first surface and a second surface opposite to the first surface, the base layer defining first openings respectively corresponding to the unit areas;
a pattern insulating layer comprising a material having a thermal expansion coefficient that is greater than a thermal expansion coefficient of the base layer, the pattern insulating layer having pattern portions respectively corresponding to the unit areas on the first surface of the base layer, each of the pattern portions defining a plurality of slits; and
a reinforcement pattern in the peripheral area, the reinforcement pattern comprising a material having a thermal expansion coefficient that is different from the thermal expansion coefficient of the base layer, the reinforcement pattern being covered by the pattern insulating layer.

2. The mask for deposition of claim 1, wherein the thermal expansion coefficient of the reinforcement pattern is greater than the thermal expansion coefficient of the base layer, and
wherein the reinforcement pattern is on the second surface of the base layer.

3. The mask for deposition of claim 2, wherein the pattern insulating layer has:
a first portion on the first surface of the base layer and comprising the pattern portions; and
a second portion on the second surface of the base layer and defining second openings respectively corresponding to the unit areas, and
wherein the reinforcement pattern is covered by the second portion of the pattern insulating layer.

4. The mask for deposition of claim 3, further comprising an alignment pattern in the peripheral area on the first surface of the base layer and covered by the first portion of the pattern insulating layer.

5. The mask for deposition of claim 4, wherein the reinforcement pattern is spaced apart from the alignment pattern with the base layer interposed therebetween.

6. The mask for deposition of claim 4, wherein a size of the reinforcement pattern is greater than a size of the alignment pattern in the plan view.

7. The mask for deposition of claim 3, wherein the first portion of the pattern insulating layer defines an alignment opening positioned in the peripheral area.

8. The mask for deposition of claim 7, wherein the reinforcement pattern overlaps the alignment opening in the plan view.

9. The mask for deposition of claim 3, wherein the peripheral area has an alignment opening extending through the base layer, the pattern insulating layer, and the reinforcement pattern in a direction perpendicular to the first surface of the base layer.

10. The mask for deposition of claim 1, wherein the thermal expansion coefficient of the reinforcement pattern is less than the thermal expansion coefficient of the base layer, and
wherein the reinforcement pattern is on the first surface of the base layer.

11. The mask for deposition of claim 10, wherein the pattern insulating layer has:
a first portion on the first surface of the base layer and comprising the pattern portions; and
a second portion on the second surface of the base layer and defining second openings respectively corresponding to the unit areas, and
wherein the reinforcement pattern is covered by the first portion of the pattern insulating layer.

12. The mask for deposition of claim 11, further comprising an alignment pattern in the peripheral area on the first surface of the base layer and covered by the first portion of the pattern insulating layer,
wherein the alignment pattern and the reinforcement pattern comprise a same material.

13. The mask for deposition of claim 12, wherein the reinforcement pattern and the alignment pattern are spaced apart from each other.

14. The mask for deposition of claim 13, wherein the reinforcement pattern surrounds the alignment pattern in the plan view.

15. The mask for deposition of claim 1, further comprising a cover insulating layer between the base layer and the pattern insulating layer in the peripheral area,
wherein the reinforcement pattern is between the cover insulating layer and the pattern insulating layer.

16. The mask for deposition of claim 15, wherein the base layer comprises silicon, the cover insulating layer comprises silicon oxide, the pattern insulating layer comprises silicon nitride, and the reinforcement pattern comprises a metal or an alloy.

17. The mask for deposition of claim 1, wherein the reinforcement pattern is adjacent to an edge of the base layer.

18. A mask for deposition comprising:
a plurality of unit areas spaced apart from each other and a peripheral area surrounding the unit areas in a plan view;
a base layer having a first surface and a second surface opposite to the first surface, the base layer defining first openings respectively corresponding to the unit areas;
a pattern insulating layer comprising a material having a thermal expansion coefficient that is greater than a thermal expansion coefficient of the base layer, the pattern insulating layer has:
a first portion on the first surface of the base layer, the first portion comprising pattern portions respectively corresponding to the unit areas, each of the pattern portions defining a plurality of slits; and
a second portion on the second surface of the base layer, the second portion defining second openings respectively corresponding to the unit areas; and
a cover insulating layer comprising a material having a thermal expansion coefficient that is less than the thermal expansion coefficient of the base layer, the cover insulating layer being between the base layer and the first portion of the pattern insulating layer, the cover insulating layer defining third openings respectively corresponding to the unit areas,
wherein the first surface of the base layer contacts the cover insulating layer, and the second surface of the base layer contacts the second portion of the pattern insulating layer.

19. The mask for deposition of claim 18, wherein a size of one of the second openings is greater than a size of corresponding one of the first openings in the plan view.

20. An electronic device comprising:
a display device comprising an emission layer deposited by using a mask for deposition; and
a processor configured to provide an image data signal and an input control signal to the display device to control the display device,
wherein the mask comprises:
a plurality of unit areas spaced apart from each other and a peripheral area surrounding the unit areas in a plan view;
a base layer having a first surface and a second surface opposite to the first surface, the base layer defining first openings respectively corresponding to the unit areas;
a pattern insulating layer comprising a material having a thermal expansion coefficient that is greater than a thermal expansion coefficient of the base layer, the pattern insulating layer comprising pattern portions respectively corresponding to the unit areas on the first surface of the base layer, each of the pattern portions defining a plurality of slits; and
a reinforcement pattern in the peripheral area, the reinforcement pattern comprising a material having a thermal expansion coefficient that is different from the thermal expansion coefficient of the base layer, the reinforcement pattern being covered by the pattern insulating layer.
